(19) United States
(12) Patent Application Publication
(10) Pub. No.: US 2024/0338177 A1
(43) Pub. Date: Oct. 10, 2024

(54) ANALOG COMPUTATION-IN-MEMORY ENGINE AND DIGITAL COMPUTATION-IN-MEMORY ENGINE TO PERFORM OPERATIONS IN A NEURAL NETWORK

(71) Applicant: Silicon Storage Technology, Inc., San Jose, CA (US)

(72) Inventor: Hieu Van Tran, San Jose, CA (US)

(21) Appl. No.: 18/218,368

(22) Filed: Jul. 5, 2023

Related U.S. Application Data
(60) Provisional application No. 63/458,439, filed on Apr. 10, 2023.

(51) Int. Cl. G06F 7/523; G06F 7/501; G06F 17/16; G11C 11/54

(52) U.S. Cl. CPC G06F 7/523; G06F 7/501; G06F 17/16; G11C 11/54

(57) ABSTRACT

In one example disclosed herein, a system comprises an analog computation-in-memory engine to perform operations in a first layer in a neural network and a digital computation-in-memory engine to perform operations in a second layer different than the first layer in the neural network. The system optionally comprises a dynamic weight engine to perform operations in a third layer different than the first layer and the second layer in the neural network.

### PRIORITY CLAIM

This application claims priority to U.S. Provisional Patent Application No. 63/458,439, filed on Apr. 10, 2023, and titled, “Neural Network Comprising Analog Computation-in-Memory Engine and Digital Computation-in-Memory Engine,” which is incorporated by reference herein.

### FIELD OF THE INVENTION

Numerous examples are disclosed of a system comprising one or more analog computation-in-memory engines and one or more digital computation-in-memory engines to perform neural network operations.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are well known. For example, U.S. Pat. No. 5,029,130 (“the '130patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |
| Program | 1-2 | V | 10.5-3 | μA | 9-10 | V |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |
| Erase | −0.5 V/0 V | | 0 | V | 0 V/−8 V | | 8-12 | V | 0 | V |
| Program | 1 | V | 0.1-1 | μA | 8-11 | V | 4.5-9 | V | 4.5-5 | V |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | | |
|---|---|---|---|---|---|---|---|---|
| Program | 1 | V | 0.2-3 | μA | 4.5 | V | 7-9 | V |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | | BL | | SL | | Substrate | |
|---|---|---|---|---|---|---|---|---|
| Read | 2-5 | V | 0.6-2 | V | 0 | V | 0 | V |
| Erase | −8 to −10 V/0 V | | FLT | | FLT | | 8-10 V/15-20 V | |
| Program | 8-12 | V | 3-5 | V | 0 | V | 0 | V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network. A non-volatile memory array and associated circuitry used in a neural network is one type of computation-in-memory (CIM) engine or vector-by-matrix (VMM) multiplication system.

S0 is the input layer, which for this example is a 32×32 pixel RGB image with 5 bit precision (i.e. three 32×32 pixel arrays, one for each color R, G and B, each pixel being 5 bit precision). The synapses CB1 going from input layer S0 to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer S0 (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two-dimensional array, and thus in this example layer C1 constitutes 16 layers of two-dimensional arrays (keeping in mind that the layers and arrays referenced herein are logical relationships, not necessarily physical relationships—i.e., the arrays are not necessarily oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the need for separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g., C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32e. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog to analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a,32b,32c,32d,32e): one input layer (32a), two hidden layers (32b,32c), and two fully connected layers (32d,32e). One of ordinary skill in the art will appreciate that this is merely an example and that a system instead could comprise more than two hidden layers and more than two fully connected layers.

### Vector-by-Matrix Multiplication (VMM) Arrays

FIG. 9 depicts neuron VMM array 900, which is particularly suited for memory cells 310 as shown in FIG. 3 and is utilized as the synapses and parts of neurons between an input layer and the next layer. VMM array 900 comprises memory array 901 of non-volatile memory cells and reference array 902 (at the top of the array) of non-volatile reference memory cells. Alternatively, another reference array can be placed at the bottom.

In VMM array 900, control gate lines, such as control gate line 903, run in a vertical direction (hence reference array 902 in the row direction is orthogonal to control gate line 903), and erase gate lines, such as erase gate line 904, run in a horizontal direction. Here, the inputs to VMM array 900 are provided on the control gate lines (CG0, CG1, CG2, CG3), and the output of VMM array 900 emerges on the source lines (SL0, SL1). In one example, only even rows are used, and in another example, only odd rows are used. The current placed on each source line (SL0, SL1, respectively) performs a summing function of all the currents from the memory cells connected to that particular source line.

As described herein for neural networks, the non-volatile memory cells of VMM array 900, i.e., the memory cells 310 of VMM array 900, may be configured to operate in a sub-threshold region.

The non-volatile reference memory cells and the non-volatile memory cells described herein are biased in weak inversion (sub threshold region):

$$Ids = Io * {e}^{( Vg - Vth ) / n V t} = w * Io * {e}^{( Vg ) / nVt} ,$$

$$where w = {e}^{( - Vth ) / nVt}$$

where Ids is the drain to source current; Vg is gate voltage on the memory cell; Vth is threshold voltage of the memory cell; Vt is thermal voltage=k*T/q with k being the Boltzmann constant, T the temperature in Kelvin, and q the electronic charge; n is a slope factor=1+(Cdep/Cox) with Cdep=capacitance of the depletion layer, and Cox capacitance of the gate oxide layer; Io is the memory cell current at gate voltage equal to threshold voltage, Io is proportional to (Wt/L)*u*Cox* (n−1) * Vt² where u is carrier mobility and Wt and L are width and length, respectively, of the memory cell.

For an I-to-V log converter using a memory cell (such as a reference memory cell or a peripheral memory cell) or a transistor to convert input current into an input voltage:

$$Vg = n * Vt * log [ Ids / wp * Io ]$$

where, wp is w of a reference or peripheral memory cell.

For a memory array used as a vector matrix multiplier VMM array with the current input, the output current is:

$$Iout = wa * Io * {e}^{( Vg ) / nVt} , namely$$

$$Iout = ( wa / wp ) * Iin = W * Iin$$

$$W = {e}^{( Vthp - Vtha ) / nVt}$$

Here, wa=w of each memory cell in the memory array.
Vthp is effective threshold voltage of the peripheral memory cell and Vtha is effective threshold voltage of the main (data) memory cell. Note that the threshold voltage of a transistor is a function of substrate body bias voltage and the substrate body bias voltage, denoted Vsb, can be modulated to compensate for various conditions, on such temperature. The threshold voltage Vth can be expressed as:

$$Vth = Vth 0 + gamma ( SQRT \vert Vsb - 2 * φ F ) - SQRT \vert 2 * φ F \vert )$$

where Vth0 is threshold voltage with zero substrate bias, φF is a surface potential, and gamma is a body effect parameter.

A wordline or control gate can be used as the input for the memory cell for the input voltage.

Alternatively, the flash memory cells of VMM arrays described herein can be configured to operate in the linear region:

$$Ids = beta * ( Vgs - Vth ) * Vds ; beta = u * Cox * Wt / L$$

$$W = α ( Vgs - Vth )$$

meaning weight W in the linear region is proportional to (Vgs-Vth)

A wordline or control gate or bitline or sourceline can be used as the input for the memory cell operated in the linear region. The bitline or sourceline can be used as the output for the memory cell.

For an I-to-V linear converter, a memory cell (such as a reference memory cell or a peripheral memory cell) or a transistor operating in the linear region can be used to linearly convert an input/output current into an input/output voltage.

Alternatively, the memory cells of VMM arrays described herein can be configured to operate in the saturation region:

$$Ids = 1 / 2 * beta * {( Vgs - Vth )}^{2} ; beta = u * Cox * Wt / L$$

$$W {α ( Vgs - Vth )}^{2} , meaning weight W is proportional to {( Vgs - Vth )}^{2}$$

A wordline, control gate, or erase gate can be used as the input for the memory cell operated in the saturation region. The bitline or sourceline can be used as the output for the output neuron.

Alternatively, the memory cells of VMM arrays described herein can be used in all regions or a combination thereof (sub threshold, linear, or saturation) for each layer or multi layers of a neural network.

Other examples for VMM array 32 of FIG. 7 are described in U.S. Pat. No. 10,748,630, which is incorporated by reference herein. As described in that application. a sourceline or a bitline can be used as the neuron output (current summation output).

FIG. 10 depicts neuron VMM array 1000, which is particularly suited for memory cells 210 as shown in FIG. 2 and is utilized as the synapses between an input layer and the next layer. VMM array 1000 comprises a memory array 1003 of non-volatile memory cells, reference array 1001 of first non-volatile reference memory cells, and reference array 1002 of second non-volatile reference memory cells. Reference arrays 1001 and 1002, arranged in the column direction of the array, serve to convert current inputs flowing into terminals BLR0, BLR1, BLR2, and BLR3 into voltage inputs WL0, WL1, WL2, and WL3. In effect, the first and second non-volatile reference memory cells are diode-connected through multiplexors 1014 (only partially depicted) with current inputs flowing into them. The reference cells are tuned (e.g., programmed) to target reference levels. The target reference levels are provided by a reference mini-array matrix (not shown).

Memory array 1003 serves two purposes. First, it stores the weights that will be used by the VMM array 1000 on respective memory cells thereof. Second, memory array 1003 effectively multiplies the inputs (i.e. current inputs provided in terminals BLR0, BLR1, BLR2, and BLR3, which reference arrays 1001 and 1002 convert into the input voltages to supply to wordlines WL0, WL1, WL2, and WL3) by the weights stored in the memory array 1003 and then adds all the results (memory cell currents) to produce the output on the respective bit lines (BL0-BLN), which will be the input to the next layer or input to the final layer. By performing the multiplication and addition function, memory array 1003 negates the need for separate multiplication and addition logic circuits and is also power efficient. Here, the voltage inputs are provided on the word lines WL0, WL1, WL2, and WL3, and the output emerges on the respective bit lines BL0-BLN during a read (inference) operation. The current placed on each of the bit lines BL0-BLN performs a summing function of the currents from all non-volatile memory cells connected to that particular bitline.

Table No. 5 depicts operating voltages and currents for VMM array 1000. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO. 5
Operation of VMM Array 1000 of FIG. 10:

| | WL | | WL -unsel | BL | | BL -unsel | SL | | SL -unsel |
|---|---|---|---|---|---|---|---|---|---|
| Read | 1-3.5 | V | −0.5 V/0 V | 0.6-2 V (Ineuron) | | 0.6 V-2 V/0 V | 0 | V | 0 V |
| Erase | ~5-13 | V | 0 V | 0 | V | 0 V | 0 | V | 0 V |
| Program | 1-2 | V | −0.5 V/0 V | 0.1-3 | uA | Vinh ~2.5 V | 4-10 | V | 0-1 V/FLT |

FIG. 11 depicts neuron VMM array 1100, which is particularly suited for memory cells 210 as shown in FIG. 2 and is utilized as the synapses and parts of neurons between an input layer and the next layer. VMM array 1100 comprises a memory array 1103 of non-volatile memory cells, reference array 1101 of first non-volatile reference memory cells, and reference array 1102 of second non-volatile reference memory cells. Reference arrays 1101 and 1102 run in row direction of the VMM array 1100. VMM array is similar to VMM 1000 except that in VMM array 1100, the word lines run in the vertical direction. Here, the inputs are provided on the word lines (WLA0, WLB0, WLA1, WLB2, WLA2, WLB2, WLA3, WLB3), and the output emerges on the source line (SL0, SL1) during a read operation. The current placed on each source line performs a summing function of all the currents from the memory cells connected to that particular source line.

Table No. 6 depicts operating voltages and currents for VMM array 1100. The columns in the table indicate the voltages placed on word lines for selected cells, word lines for unselected cells, bit lines for selected cells, bit lines for unselected cells, source lines for selected cells, and source lines for unselected cells. The rows indicate the operations of read, erase, and program.

TABLE NO. 6
Operation of VMM Array 1100 of FIG. 11

| | WL | | WL -unsel | BL | | BL -unsel | SL | | SL -unsel |
|---|---|---|---|---|---|---|---|---|---|
| Read | 1-3.5 | V | −0.5 V/0 V | 0.6-2 | V | 0.6 V-2 V/0 V | ~0.3-1 V | | 0 V |
| | | | | | | | (Ineuron) | | |
| Erase | ~5-13 | V | 0 V | 0 | V | 0 V | 0 | V | SL-inhibit |
| | | | | | | | | | (~4-8 V) |
| Program | 1-2 | V | −0.5 V/0 V | 0.1-3 | uA | Vinh ~2.5 V | 4-10 | V | 0-1 V/FLT |

FIG. 12 depicts neuron VMM array 1200, which is particularly suited for memory cells 310 as shown in FIG. 3 and is utilized as the synapses and parts of neurons between an input layer and the next layer. VMM array 1200 comprises a memory array 1203 of non-volatile memory cells, reference array 1201 of first non-volatile reference memory cells, and reference array 1202 of second non-volatile reference memory cells. Reference arrays 1201 and 1202 serve to convert current inputs flowing into terminals BLR0, BLR1, BLR2, and BLR3 into voltage inputs CG0, CG1, CG2, and CG3. In effect, the first and second non-volatile reference memory cells are diode-connected through multiplexors 1212 (only partially shown) with current inputs flowing into them through BLR0, BLR1, BLR2, and BLR3. Multiplexors 1212 each include a respective multiplexor 1205 and a cascoding transistor 1204 to ensure a constant voltage on the bitline (such as BLR0) of each of the first and second non-volatile reference memory cells during a read operation. The reference cells are tuned to target reference levels.

Memory array 1203 serves two purposes. First, it stores the weights that will be used by the VMM array 1200. Second, memory array 1203 effectively multiplies the inputs (current inputs provided to terminals BLR0, BLR1, BLR2, and BLR3, for which reference arrays 1201 and 1202 convert these current inputs into the input voltages to supply to the control gates (CG0, CG1, CG2, and CG3) by the weights stored in the memory array and then add all the results (cell currents) to produce the output, which appears on BL0-BLN, and will be the input to the next layer or input to the final layer. By performing the multiplication and addition function, the memory array negates the need for separate multiplication and addition logic circuits and is also power efficient. Here, the inputs are provided on the control gate lines (CG0, CG1, CG2, and CG3), and the output emerges on the bit lines (BL0-BLN) during a read operation. The current placed on each bitline performs a summing function of all the currents from the memory cells connected to that particular bitline.

VMM array 1200 implements uni-directional tuning for non-volatile memory cells in memory array 1203. That is, each non-volatile memory cell is erased and then partially programmed until the desired charge on the floating gate is reached. If too much charge is placed on the floating gate (such that the wrong value is stored in the cell), the cell is erased, and the sequence of partial programming operations starts over. As shown, two rows sharing the same erase gate (such as EG0 or EG1) are erased together (which can be referred to as a page erase), and thereafter, each cell is partially programmed until the desired charge on the floating gate is reached.

Table No. 7 depicts operating voltages and currents for VMM array 1200. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO. 7
Operation of VMM Array 1200 of FIG. 12

| | | | | | | | | | CG - | | | | | | | | | |
|---|---|---|---|---|---|---|---|---|---|---|---|---|---|---|---|---|---|---|
| | | | | | | | | | unsel | | | | | | | | | |
| | | | WL - | | | BL - | | | same | CG - | | | EG - | | | | SL - | |
| | WL | | unsel | BL | | unsel | CG | | sector | unsel | EG | | unsel | | SL | | unsel | |
| Read | 1.0-2 | V | −0.5 V/0 V | 0.6-2 V | | 0 V | 0-2.6 | V | 0-2.6 V | 0-2.6 V | 0-2.6 | V | 0-2.6 | V | 0 | V | 0 | V |
| | | | | (Ineuron) | | | | | | | | | | | | | | |
| Erase | 0 | V | 0 V | 0 | V | 0 V | 0 | V | 0-2.6 V | 0-2.6 V | 5-12 | V | 0-2.6 | V | 0 | V | 0 | V |
| Program | 0.7-1 | V | −0.5 V/0 V | 0.1-1 | uA | Vinh | 4-11 | V | 0-2.6 V | 0-2.6 V | 4.5-5 | V | 0-2.6 | V | 4.5-5 | V | 0-1 | V |
| | | | | | | (1-2 V) | | | | | | | | | | | | |

FIG. 13 depicts neuron VMM array 1300, which is particularly suited for memory cells 310 as shown in FIG. 3 and is utilized as the synapses and parts of neurons between an input layer and the next layer. VMM array 1300 comprises a memory array 1303 of non-volatile memory cells, reference array 1301 or first non-volatile reference memory cells, and reference array 1302 of second non-volatile reference memory cells. EG lines EGR0, EG0, EG1 and EGR1 are run vertically while CG lines CG0, CG1, CG2 and CG3 and SL lines WL0, WL1, WL2 and WL3 are run horizontally. VMM array 1300 is similar to VMM array 1400, except that VMM array 1300 implements bi-directional tuning, where each individual cell can be completely erased, partially programmed, and partially erased as needed to reach the desired amount of charge on the floating gate due to the use of separate EG lines. As shown, reference arrays 1301 and 1302 convert input current in the terminal BLR0, BLR1, BLR2, and BLR3 into control gate voltages CG0, CG1, CG2, and CG3 (through the action of diode-connected reference cells through multiplexors 1314) to be applied to the memory cells in the row direction. The current output (neuron) is in the bit lines BL0-BLN, where each bit line sums all currents from the non-volatile memory cells connected to that particular bitline.

Table No. 8 depicts operating voltages and currents for VMM array 1300. The columns in the table indicate the voltages placed on word lines for selected cells, word lines for unselected cells, bit lines for selected cells, bit lines for unselected cells, control gates for selected cells, control gates for unselected cells in the same sector as the selected cells, control gates for unselected cells in a different sector than the selected cells, erase gates for selected cells, erase gates for unselected cells, source lines for selected cells, and source lines for unselected cells. The rows indicate the operations of read, erase, and program.

TABLE NO. 8
Operation of VMM Array 1300 of FIG. 13

| | | | | | | | | | CG - | | | | | | | | | |
|---|---|---|---|---|---|---|---|---|---|---|---|---|---|---|---|---|---|---|
| | | | | | | | | | unsel | | | | | | | | | |
| | | | WL - | | | BL - | | | same | | CG - | | | EG - | | | SL - | |
| | WL | | unsel | BL | | unsel | CG | | sector | | unsel | EG | | unsel | SL | | unsel | |
| Read | 1.0-2 | V | −0.5 V/0 V | 0.6-2 V | | 0 V | 0-2.6 | V | 0-2.6 | V | 0-2.6 V | 0-2.6 | V | 0-2.6 V | 0 | V | 0 | V |
| | | | | (Ineuron) | | | | | | | | | | | | | | |
| Erase | 0 | V | 0 V | 0 | V | 0 V | 0 | V | 4-9 | V | 0-2.6 V | 5-12 | V | 0-2.6 V | 0 | V | 0 | V |
| Program | 0.7-1 | V | −0.5 V/0 V | 0.1-1 | uA | Vinh | 4-11 | V | 0-2.6 | V | 0-2.6 V | 4.5-5 | V | 0-2.6 V | 4.5-5 | V | 0-1 | V |
| | | | | | | (1-2 V) | | | | | | | | | | | | |

FIG. 22 depicts neuron VMM array 2200, which is particularly suited for memory cells 210 as shown in FIG. 2 and is utilized as the synapses and parts of neurons between an input layer and the next layer. In VMM array 2200, the inputs INPUT₀ . . . , INPUT_{N} are received on bit lines BL₀, . . . BL_{N}, respectively, and the outputs OUTPUT₁, OUTPUT₂, OUTPUT₃, and OUTPUT₄ are generated on source lines SL₀, SL₁, SL₂, and SL₃, respectively.

FIG. 23 depicts neuron VMM array 2300, which is particularly suited for memory cells 210 as shown in FIG. 2 and is utilized as the synapses and parts of neurons between an input layer and the next layer. In this example, the inputs INPUT₀, INPUT₁, INPUT₂, and INPUT₃ are received on source lines SL₀, SL₁, SL₂, and SL₃, respectively, and the outputs OUTPUT₀, . . . OUTPUT_{N} are generated on bit lines BL₀, . . . , BL_{N}.

FIG. 24 depicts neuron VMM array 2400, which is particularly suited for memory cells 210 as shown in FIG. 2 and is utilized as the synapses and parts of neurons between an input layer and the next layer. In this example, the inputs INPUT₀ . . . , INPUT_{M} are received on word lines WL₀, . . . , WL_{M}, respectively, and the outputs OUTPUT₀, . . . OUTPUT_{N} are generated on bit lines BL₀, . . . , BL_{N}.

FIG. 25 depicts neuron VMM array 2500, which is particularly suited for memory cells 310 as shown in FIG. 3 and is utilized as the synapses and parts of neurons between an input layer and the next layer. In this example, the inputs INPUT₀ . . . , INPUT_{M} are received on word lines WL₀, . . . , WL_{M}, respectively, and the outputs OUTPUT₀, . . . OUTPUT_{N} are generated on bit lines BL₀, . . . , BL_{N}.

FIG. 26 depicts neuron VMM array 2600, which is particularly suited for memory cells 410 as shown in FIG. 4 and is utilized as the synapses and parts of neurons between an input layer and the next layer. In this example, the inputs INPUT₀ . . . , INPUTₙ are received on vertical control gate lines CG₀, . . . , CG_{N}, respectively, and the outputs OUTPUT₁ and OUTPUT₂ are generated on source lines SL₀ and SL₁.

FIG. 27 depicts neuron VMM array 2700, which is particularly suited for memory cells 410 as shown in FIG. 4 and is utilized as the synapses and parts of neurons between an input layer and the next layer. In this example, the inputs INPUT₀ . . . , INPUT_{N} are received on the gates of bit line control gates 2701-1, 2701-2, . . . , 2701-(N−1), and 2701-N, respectively, which are coupled to bit lines BL₀, . . . , BL_{N}, respectively. Example outputs OUTPUT₁ and OUTPUT₂ are generated on source lines SL₀ and SL₁.

FIG. 28 depicts neuron VMM array 2800, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on word lines WL₀, . . . , WL_{M}, and the outputs OUTPUT₀ . . . , OUTPUT_{N} are generated on bit lines BL₀, . . . , BL_{N}, respectively.

FIG. 29 depicts neuron VMM array 2900, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on control gate lines CG₀, . . . , CG_{M}. Outputs OUTPUT₀ . . . , OUTPUT_{N} are generated on vertical source lines SL₀, . . . , SL_{N}, respectively, where each source line SLᵢ is coupled to the source lines of all memory cells in column i.

FIG. 30 depicts neuron VMM array 3000, which is particularly suited for memory cells 310 as shown in FIG. 3, memory cells 510 as shown in FIG. 5, and memory cells 710 as shown in FIG. 7, and is utilized as the synapses and parts of neurons between an input layer and the next layer. In this example, the inputs INPUT₀ . . . , INPUT_{M} are received on control gate lines CG₀, . . . , CG_{M}. Outputs OUTPUT₀ . . . , OUTPUT_{N} are generated on vertical bit lines BL₀, . . . , BL_{N}, respectively, where each bit line BLᵢ is coupled to the bit lines of all memory cells in column i.

### Long Short-Term Memory

The prior art includes a concept referred to as long short-term memory (LSTM). LSTM units often are used in neural networks. LSTM allows a neural network to remember information over predetermined arbitrary time intervals and to use that information in subsequent operations. A conventional LSTM unit comprises a cell, an input gate, an output gate, and a forget gate. The three gates regulate the flow of information into and out of the cell and the time interval that the information is remembered in the LSTM. VMMs are particularly useful in LSTM units.

FIG. 14 depicts an example LSTM 1400. LSTM 1400 in this example comprises cells 1401, 1402, 1403, and 1404. Cell 1401 receives input vector x₀ and generates output vector h₀ and cell state vector c₀. Cell 1402 receives input vector x₁, the output vector (hidden state) h₀ from cell 1401, and cell state c₀ from cell 1401 and generates output vector h₁ and cell state vector c₁. Cell 1403 receives input vector x₂, the output vector (hidden state) h₁ from cell 1402, and cell state c₁ from cell 1402 and generates output vector h₂ and cell state vector c₂. Cell 1404 receives input vector x₃, the output vector (hidden state) h₂ from cell 1403, and cell state c₂ from cell 1403 and generates output vector h₃. Additional cells can be used, and an LSTM with four cells is merely an example.

FIG. 15 depicts an example implementation of an LSTM cell 1500, which can be used for cells 1401, 1402, 1403, and 1404 in FIG. 14. LSTM cell 1500 receives input vector x(t), cell state vector c(t−1) from a preceding cell, and output vector h(t−1) from a preceding cell, and generates cell state vector c(t) and output vector h(t).

LSTM cell 1500 comprises sigmoid function devices 1501, 1502, and 1503, each of which applies a number between 0 and 1 to control how much of each component in the input vector is allowed through to the output vector. LSTM cell 1500 also comprises tanh devices 1504 and 1505 to apply a hyperbolic tangent function to an input vector, multiplier devices 1506, 1507, and 1508 to multiply two vectors together, and addition device 1509 to add two vectors together. Output vector h(t) can be provided to the next LSTM cell in the system, or it can be accessed for other purposes.

FIG. 16 depicts an LSTM cell 1600, which is an example of an implementation of LSTM cell 1500. For the reader's convenience, the same numbering from LSTM cell 1500 is used in LSTM cell 1600. Sigmoid function devices 1501, 1502, and 1503 and tanh device 1504 each comprise multiple VMM arrays 1601 and activation function blocks 1602. Thus, it can be seen that VMM arrays are particular useful in LSTM cells used in certain neural network systems. The multiplier devices 1506, 1507, and 1508 and the addition device 1509 are implemented in a digital manner or in an analog manner. The activation function blocks 1602 can be implemented in a digital manner or in an analog manner.

An alternative to LSTM cell 1600 (and another example of an implementation of LSTM cell 1500) is shown in FIG. 17. In FIG. 17, sigmoid function devices 1501, 1502, and 1503 and tanh device 1504 share the same physical hardware (VMM arrays 1701 and activation function block 1702) in a time-multiplexed fashion. LSTM cell 1700 also comprises multiplier device 1703 to multiply two vectors together, addition device 1708 to add two vectors together, tanh device 1505 (which comprises activation function block 1702), register 1707 to store the value i(t) when i(t) is output from sigmoid function block 1702, register 1704 to store the value f(t) * c(t−1) when that value is output from multiplier device 1703 through multiplexor 1710, register 1705 to store the value i(t) * u(t) when that value is output from multiplier device 1703 through multiplexor 1710, and register 1706 to store the value o(t) * c˜(t) when that value is output from multiplier device 1703 through multiplexor 1710, and multiplexor 1709.

Whereas LSTM cell 1600 contains multiple sets of VMM arrays 1601 and respective activation function blocks 1602, LSTM cell 1700 contains one set of VMM arrays 1701 and activation function block 1702, which are used to represent multiple layers in the example of LSTM cell 1700. LSTM cell 1700 will require less space than LSTM 1600, as LSTM cell 1700 will require ¼ as much space for VMMs and activation function blocks compared to LSTM cell 1600.

It can be further appreciated that LSTM units will typically comprise multiple VMM arrays, each of which uses functionality provided by certain circuit blocks outside of the VMM arrays, such as a summer and activation function block and high voltage generation blocks. Providing separate circuit blocks for each VMM array would require a significant amount of space within the semiconductor device and would be somewhat inefficient. The examples described below therefore reduce the circuitry provided outside of the VMM arrays themselves.

### Gated Recurrent Units

An analog VMM implementation can be utilized for a GRU (gated recurrent unit) system. GRUs are a gating mechanism in recurrent neural networks. GRUs are similar to LSTMs, except that GRU cells generally contain fewer components than an LSTM cell.

FIG. 18 depicts an example GRU 1800. GRU 1800 in this example comprises cells 1801, 1802, 1803, and 1804. Cell 1801 receives input vector x₀ and generates output vector h₀. Cell 1802 receives input vector x₁, the output vector h₀ from cell 1801 and generates output vector h₁. Cell 1803 receives input vector x₂ and the output vector (hidden state) h₁ from cell 1802 and generates output vector h₂. Cell 1804 receives input vector x₃ and the output vector (hidden state) h₂ from cell 1803 and generates output vector h₃. Additional cells can be used, and an GRU with four cells is merely an example.

FIG. 19 depicts an example implementation of a GRU cell 1900, which can be used for cells 1801, 1802, 1803, and 1804 of FIG. 18. GRU cell 1900 receives input vector x(t) and output vector h(t−1) from a preceding GRU cell and generates output vector h(t). GRU cell 1900 comprises sigmoid function devices 1901 and 1902, each of which applies a number between 0 and 1 to components from output vector h(t−1) and input vector x(t). GRU cell 1900 also comprises a tanh device 1903 to apply a hyperbolic tangent function to an input vector, a plurality of multiplier devices 1904, 1905, and 1906 to multiply two vectors together, an addition device 1907 to add two vectors together, and a complementary device 1908 to subtract an input from 1 to generate an output.

FIG. 20 depicts a GRU cell 2000, which is an example of an implementation of GRU cell 1900. For the reader's convenience, the same numbering from GRU cell 1900 is used in GRU cell 2000. As can be seen in FIG. 20, sigmoid function devices 1901 and 1902, and tanh device 1903 each comprise multiple VMM arrays 2001 and activation function blocks 2002. Thus, it can be seen that VMM arrays are of particular use in GRU cells used in certain neural network systems. The multiplier devices 1904, 1905, 1906, the addition device 1907, and the complementary device 1908 are implemented in a digital manner or in an analog manner. The activation function blocks 2002 can be implemented in a digital manner or in an analog manner.

An alternative to GRU cell 2000 (and another example of an implementation of GRU cell 1900) is shown in FIG. 21. In FIG. 21, GRU cell 2100 utilizes VMM arrays 2101 and activation function block 2102, which when configured as a sigmoid function applies a number between 0 and 1 to control how much of each component in the input vector is allowed through to the output vector. In FIG. 21, sigmoid function devices 1901 and 1902 and tanh device 1903 share the same physical hardware (VMM arrays 2101 and activation function block 2102) in a time-multiplexed fashion. GRU cell 2100 also comprises multiplier device 2103 to multiply two vectors together, addition device 2105 to add two vectors together, complementary device 2109 to subtract an input from 1 to generate an output, multiplexor 2104, register 2106 to hold the value h(t−1) * r(t) when that value is output from multiplier device 2103 through multiplexor 2104, register 2107 to hold the value h(t−1) *z(t) when that value is output from multiplier device 2103 through multiplexor 2104, and register 2108 to hold the value h\hat{ }(t) * (1−z(t)) when that value is output from multiplier device 2103 through multiplexor 2104.

Whereas GRU cell 2000 contains multiple sets of VMM arrays 2001 and activation function blocks 2002, GRU cell 2100 contains one set of VMM arrays 2101 and activation function block 2102, which are used to represent multiple layers in the example of GRU cell 2100. GRU cell 2100 will require less space than GRU cell 2000, as GRU cell 2100 will require ⅓ as much space for VMMs and activation function blocks compared to GRU cell 2000.

It can be further appreciated that GRU systems will typically comprise multiple VMM arrays, each of which uses functionality provided by certain circuit blocks outside of the VMM arrays, such as a summer and activation function block and high voltage generation blocks. Providing separate circuit blocks for each VMM array would require a significant amount of space within the semiconductor device and would be somewhat inefficient. The examples described below therefore reduce the circuitry provided outside of the VMM arrays themselves.

### Inputs and Outputs

The input to the VMM arrays can be an analog level, a binary level, a pulse, a time modulated pulse, or digital bits (in this case a DAC is used to convert digital bits to appropriate input analog level) and the output can be an analog level, a binary level, a timing pulse, pulses, or digital bits (in this case an output ADC is used to convert output analog level into digital bits).

### Differential Cells

In general, for each memory cell in a VMM array, each weight W can be implemented by a single memory cell or by a differential cell or by two blend memory cells (average of 2 cells). In the differential cell case, two memory cells are used to implement a weight W as a differential weight (W=W+−W−). In the two blend memory cells, two memory cells are used to implement a weight W as an average of two cells.

FIG. 31 depicts VMM system 3100. In some examples, the weights, W, stored in a VMM array are stored as differential pairs, W+(positive weight) and W−(negative weight), where W=(W+)−(W−). In VMM system 3100, half of the bit lines are designated as W+lines, that is, bit lines connecting to memory cells that will store positive weights W+, and the other half of the bit lines are designated as W−lines, that is, bit lines connecting to memory cells implementing negative weights W−. The W−lines are interspersed among the W+lines in an alternating fashion. The subtraction operation is performed by a summation circuit that receives current from a W+line and a W−line, such as summation circuits 3101 and 3102. The output of a W+line and the output of a W−line are combined together to give effectively W=W+−W− for each pair of (W+, W−) cells for all pairs of (W+, W−) lines. While the above has been described in relation to W−lines interspersed among the W+lines in an alternating fashion, in other examples W+lines and W−lines can be arbitrarily located anywhere in the array.

FIG. 32 depicts another example. In VMM system 3210, positive weights W+ are implemented in first array 3211 and negative weights W− are implemented in a second array 3212, second array 3212 separate from the first array, and the resulting weights are appropriately combined together by summation circuits 3213.

FIG. 33 depicts VMM system 3300. The weights, W, stored in a VMM array are stored as differential pairs, W+(positive weight) and W−(negative weight), where W=(W+)−(W−). VMM system 3300 comprises array 3301 and array 3302. Half of the bit lines in each of array 3301 and 3302 are designated as W+lines, that is, bit lines connecting to memory cells that will store positive weights W+, and the other half of the bit lines in each of array 3301 and 3302 are designated as W−lines, that is, bit lines connecting to memory cells implementing negative weights W−. The W−lines are interspersed among the W+lines in an alternating fashion. The subtraction operation is performed by a summation circuit that receives current from a W+line and a W−line, such as summation circuits 3303, 3304, 3305, and 3306. The output of a W+line and the output of a W−line from each array 3301, 3302 are respectively combined together to give effectively W=W+−W−for each pair of (W+, W−) cells for all pairs of (W+, W−) lines. In addition, the W values from each array 3301 and 3302 can be further combined through summation circuits 3307 and 3308, such that each W value is the result of a W value from array 3301 minus a W value from array 3302, meaning that the end result from summation circuits 3307 and 3308 is a differential value of two differential values.

### Number of Weights Per Layer

Each non-volatile memory cells used in the analog neural memory system can be erased and programmed to hold a very specific and precise amount of charge, i.e., the number of electrons, in the floating gate. Each floating gate can hold one of N different values, where N is the number of different weights that can be indicated by each cell. Examples of N include 16, 32, 64, 128, and 256.

With reference again to FIGS. 6 and 8, neural networks contain a variety of layers. Certain layers do not require the use of an analog neural memory system. For example, some layers, such as the first layers of a residual neural network (RESNET), only require cells to be able to store two weights—a “0” or a “1”—i.e., N=2, which is a binary weight. Such layers do not require the use of an analog neural memory system because a simpler digital system would suffice. It is inefficient to use an analog neural memory system for such layers because the analog neural memory system provides a degree of precision (e.g., N=256) that is not utilized by layers that require N=2.

### SUMMARY OF THE INVENTION

Numerous examples are disclosed of a neural network comprising one or more analog computation-in-memory engines and one or more digital computation-in-memory engines. This allows a digital CIM engine to be used in situations where a layer contains binary weights and not analog weights.

### BRIEF DESCRIPTION OF THE DRAWINGS

FIG. 1 is a diagram that illustrates an artificial neural network.

FIG. 2 depicts a prior art split gate flash memory cell.

FIG. 3 depicts another prior art split gate flash memory cell.

FIG. 4 depicts another prior art split gate flash memory cell.

FIG. 5 depicts another prior art split gate flash memory cell.

FIG. 6 is a diagram illustrating the different levels of an example artificial neural network utilizing one or more non-volatile memory arrays.

FIG. 7 is a block diagram illustrating a VMM system.

FIG. 8 is a block diagram illustrates an example artificial neural network utilizing one or more VMM systems.

FIG. 9 depicts another example of a VMM system.

FIG. 10 depicts another example of a VMM system.

FIG. 11 depicts another example of a VMM system.

FIG. 12 depicts another example of a VMM system.

FIG. 13 depicts another example of a VMM system.

FIG. 14 depicts a prior art long short-term memory system.

FIG. 15 depicts an example cell for use in a long short-term memory system.

FIG. 16 depicts an example implementation of the cell of FIG. 15.

FIG. 17 depicts another example implementation of the cell of FIG. 15.

FIG. 18 depicts a prior art gated recurrent unit system.

FIG. 19 depicts an example cell for use in a gated recurrent unit system.

FIG. 20 depicts an example implementation t of the cell of FIG. 19.

FIG. 21 depicts another example implementation of the cell of FIG. 19.

FIG. 22 depicts another example of a VMM system.

FIG. 23 depicts another example of a VMM system.

FIG. 24 depicts another example of a VMM system.

FIG. 25 depicts another example of a VMM system.

FIG. 26 depicts another example of a VMM system.

FIG. 27 depicts another example of a VMM system.

FIG. 28 depicts another example of a VMM system.

FIG. 29 depicts another example of a VMM system.

FIG. 30 depicts another example of a VMM system.

FIG. 31 depicts another example of a VMM system.

FIG. 32 depicts another example of a VMM system.

FIG. 33 depicts another example of a VMM system.

FIG. 34 depicts an analog computation-in-memory system.

FIG. 35 depicts a digital computation-in-memory system.

FIG. 36 depicts a hybrid system comprising analog computation-in-memory systems and digital computation-in-memory systems.

FIG. 37 depicts an analog computation-in-memory engine.

FIG. 38 depicts an example digital computation-in-memory engine.

FIG. 39 depicts another example digital computation-in-memory engine.

FIG. 40 depicts another example digital computation-in-memory engine.

FIG. 41A depicts a multiply logic cell.

FIG. 41B depicts a 2-bit adder logic cell.

FIG. 41C depicts a digital CIM cell.

FIG. 42 depicts another example digital computation-in-memory-engine.

FIG. 43 depicts a shift and adder tree.

FIG. 44 depicts another shift and adder tree.

FIG. 45 depicts an example dynamic weight engine.

FIG. 46 depicts another example dynamic weight engine.

FIG. 47 depicts an integrating analog-to-digital converter.

FIG. 48 depicts an integrating analog-to-digital converter.

FIGS. 49A and 49B depict output circuits comprising a current-to-voltage converter and an analog-to-digital converter.

FIG. 50 depicts a method performed by the hybrid system of FIG. 36.

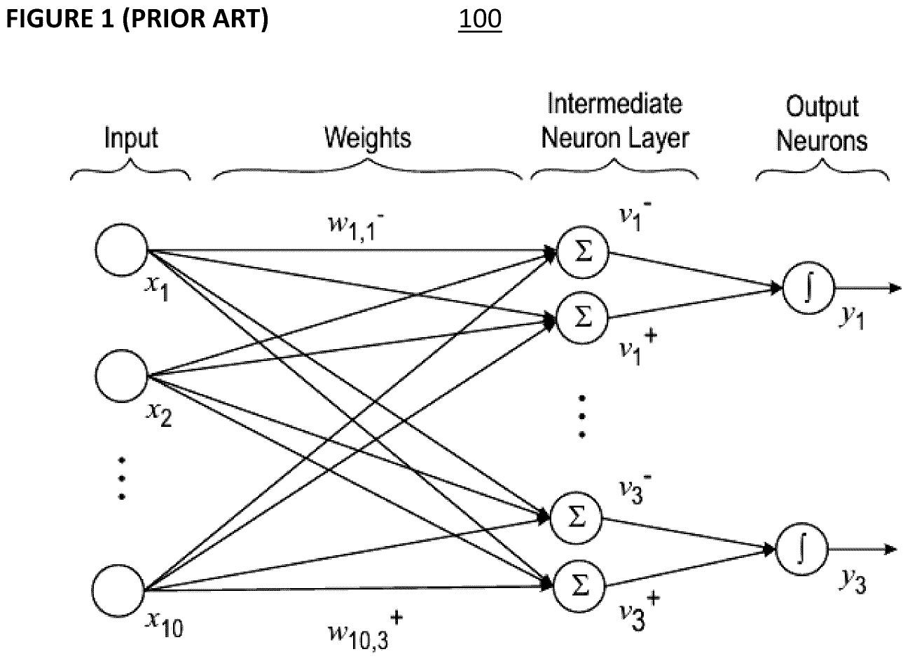

### DETAILED DESCRIPTION OF THE INVENTION

### Analog Computation-in-Memory Engine

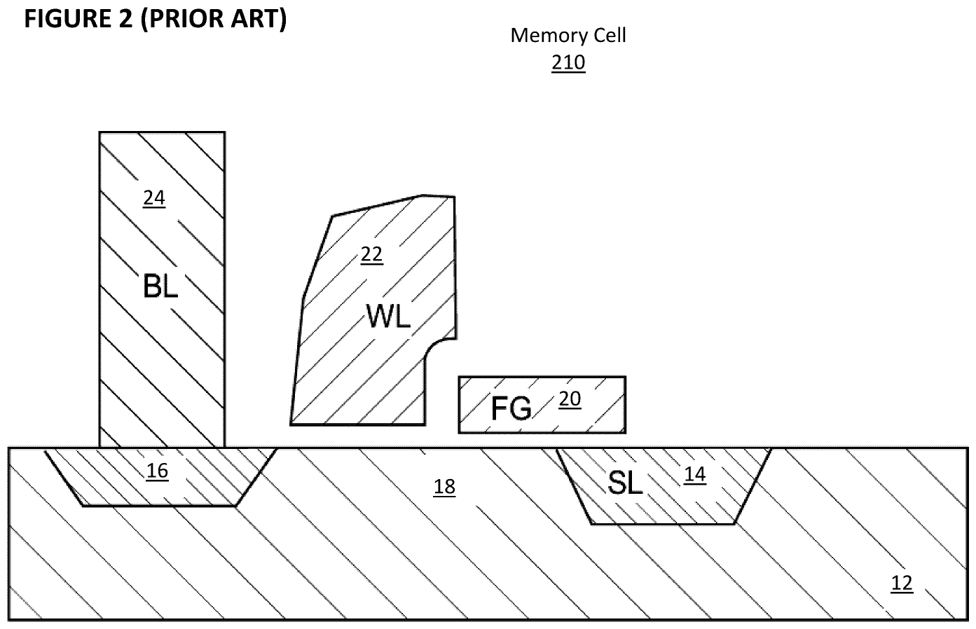

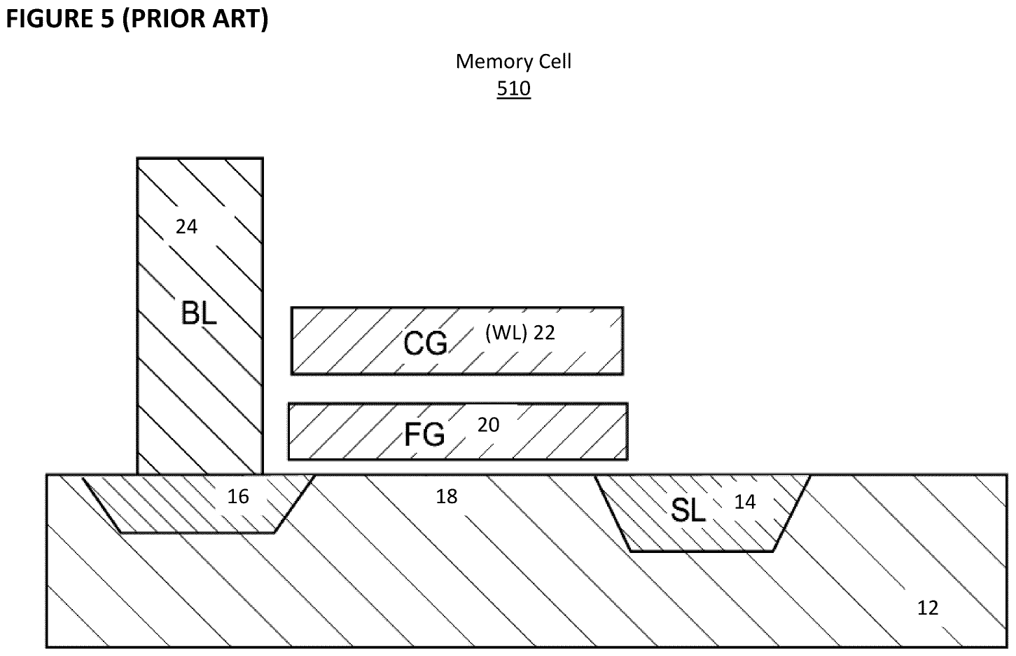

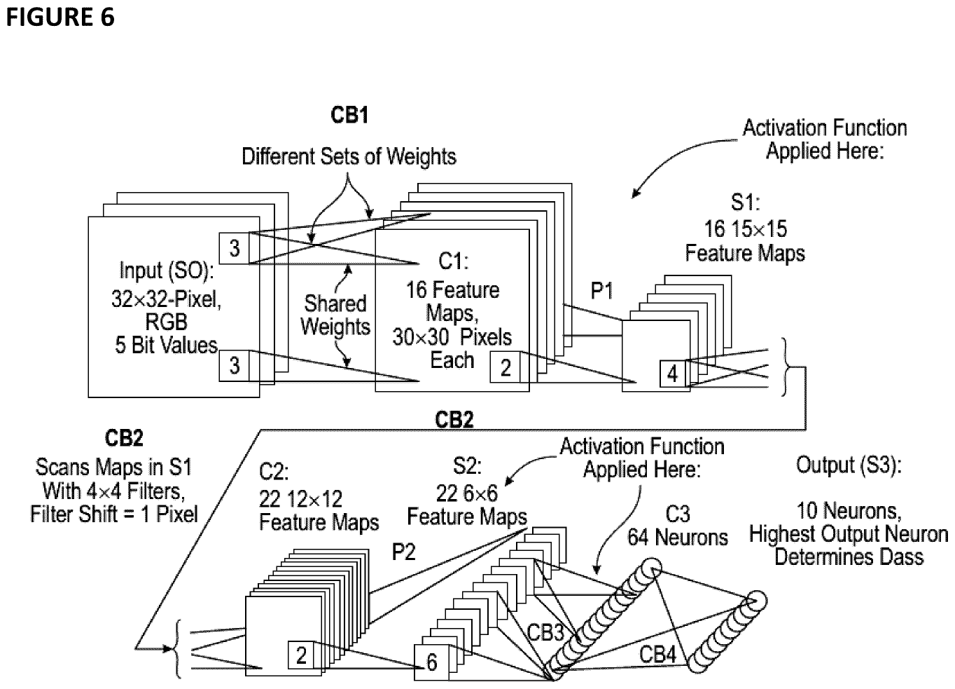

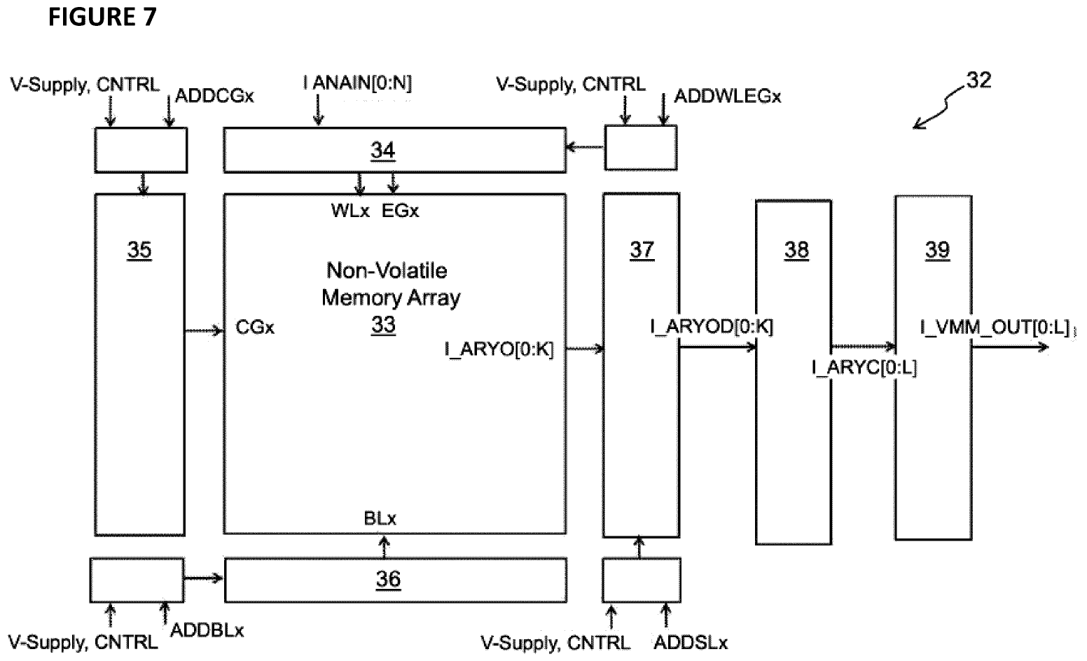

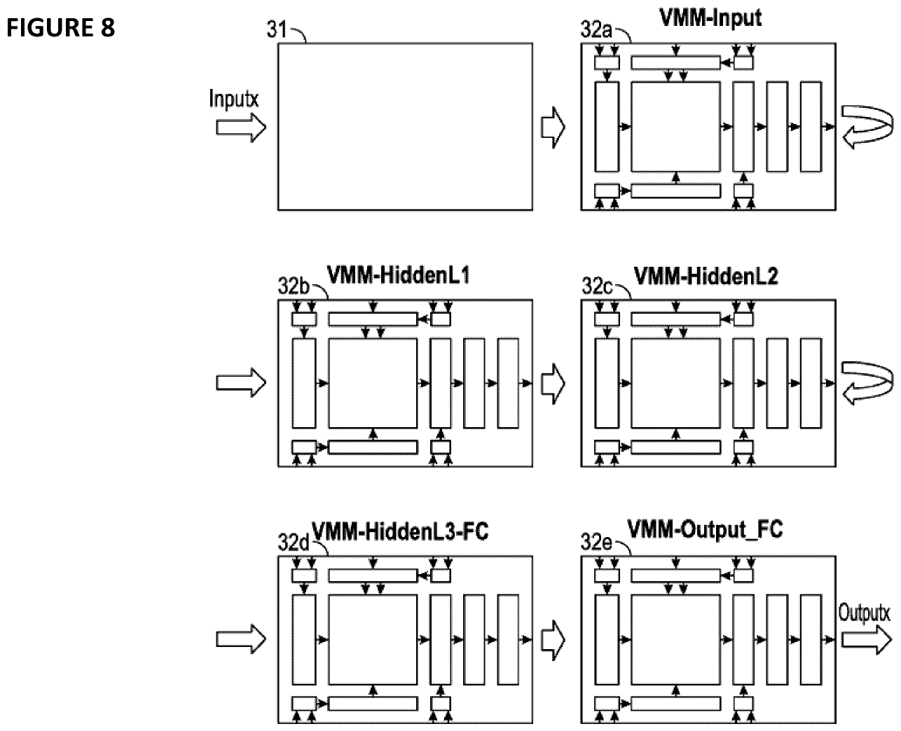

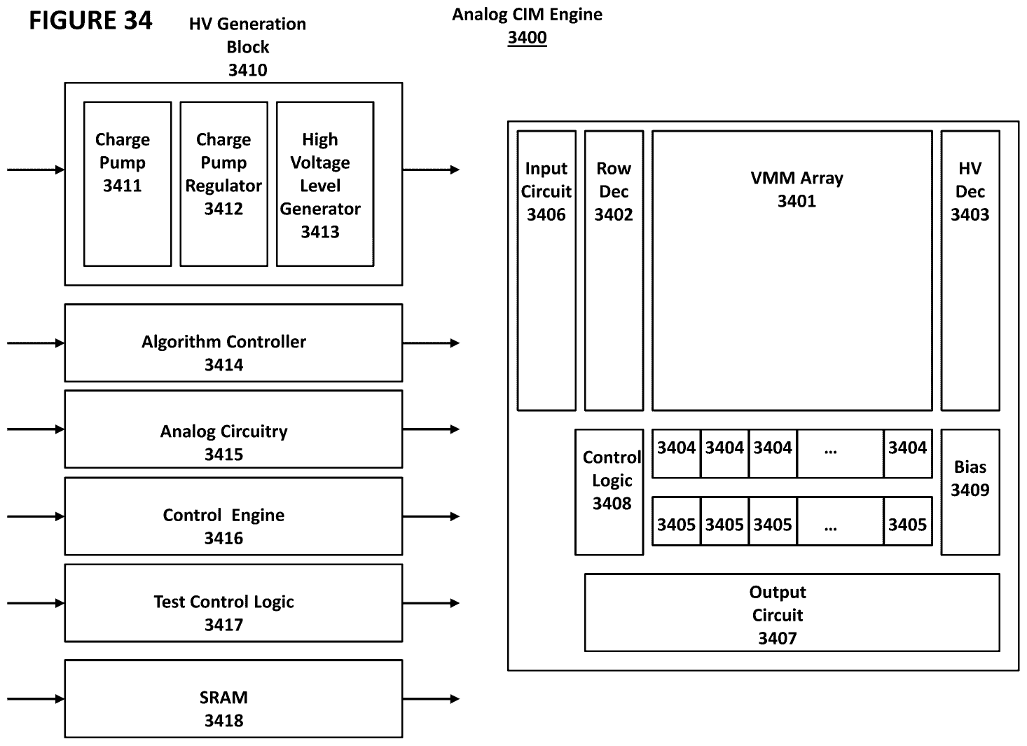

FIG. 34 depicts a block diagram of an analog computation-in-memory (CIM) engine 3400. Analog CIM engine 3400 comprises VMM array 3401 (which also can be referred to as a neural network array), row decoder 3402, high voltage decoder 3403, column decoders 3404, bit line drivers 3405 (such as bit line control circuitry for programming), input circuit 3406, output circuit 3407, control logic 3408, and bias generator 3409. Analog CIM engine 3400 further comprises high voltage generation block 3410, which comprises charge pump 3411, charge pump regulator 3412, and high voltage level generator 3413. Analog CIM engine 3400 further comprises (program/erase, or weight tuning) algorithm controller 3414, analog circuitry 3415, control engine 3416 (that may include functions such as arithmetic functions, activation functions, embedded microcontroller logic, without limitation), test control logic 3417, and static random access memory (SRAM) block 3418 to store intermediate data such as for input circuits (e.g., activation data) or output circuits (neuron output data, partial sum output neuron data) or data in for programming (such as data in for a whole row or for multiple rows). VMM array 3401 comprises an array of non-volatile memory cells arranged into rows and columns, where the non-volatile memory cells are of the type shown in FIG. 2, 3, 4, or 5 as memory cells 210, 310, 410, or 510, respectively, or are of other types known to persons of ordinary skill in the art. In one example, the non-volatile memory cells are split-gate flash memory cells as in FIG. 2, 3, or 4. In another example, the non-volatile memory cells are stacked-gate flash memory cells as in FIG. 5.

The input circuit 3406 may include circuits such as a DAC (digital to analog converter), DPC (digital to pulses converter, or digital to time modulated pulse converter), AAC (analog to analog converter, such as a current to voltage converter, or logarithmic converter), PAC (pulse to analog level converter), or any other type of converter. The input circuit 3406 may implement one or more of normalization, linear or non-linear up/down scaling functions, or arithmetic functions. The input circuit 3406 may implement a temperature compensation function for input levels. The input circuit 3406 may implement an activation function such as a rectified linear activation function (ReLU) or sigmoid. Input circuit 3406 may store digital activation data to be applied as, or combined with, an input signal during a program or read operation. The digital activation data can be stored in registers. Input circuit 3406 may comprise circuits to drive the array terminals, such as CG, WL, EG, and SL lines, which may include sample-and-hold circuits and buffers. A DAC can be used to convert digital activation data into an analog input voltage to be applied to the array.

Output circuit 3407 may include circuits such as an ITV (current-to-voltage circuit), ADC (analog to digital converter, to convert neuron analog output to digital bits), AAC (analog to analog converter, such as a current to voltage converter, or a logarithmic converter), APC (analog to pulse(s) converter, or analog to time modulated pulse converter), or any other type of converter. Output circuit 3407 may convert array outputs into activation data. Output circuit 3407 may implement an activation function such as ReLU or sigmoid. Output circuit 3407 may implement one or more of statistic normalization, regularization, up/down scaling/gain functions, statistical rounding, or arithmetic functions (e.g., add, subtract, divide, multiply, shift, log) for neuron outputs. Output circuit 3407 may implement a temperature compensation function for neuron outputs or array outputs (such as bitline output) so as to keep power consumption of the array approximately constant or to improve precision of the array (neuron) outputs such as by keeping the IV slope approximately the same over temperature. Output circuit 3407 may comprise registers for storing output data.

### Digital Computation-in-Memory

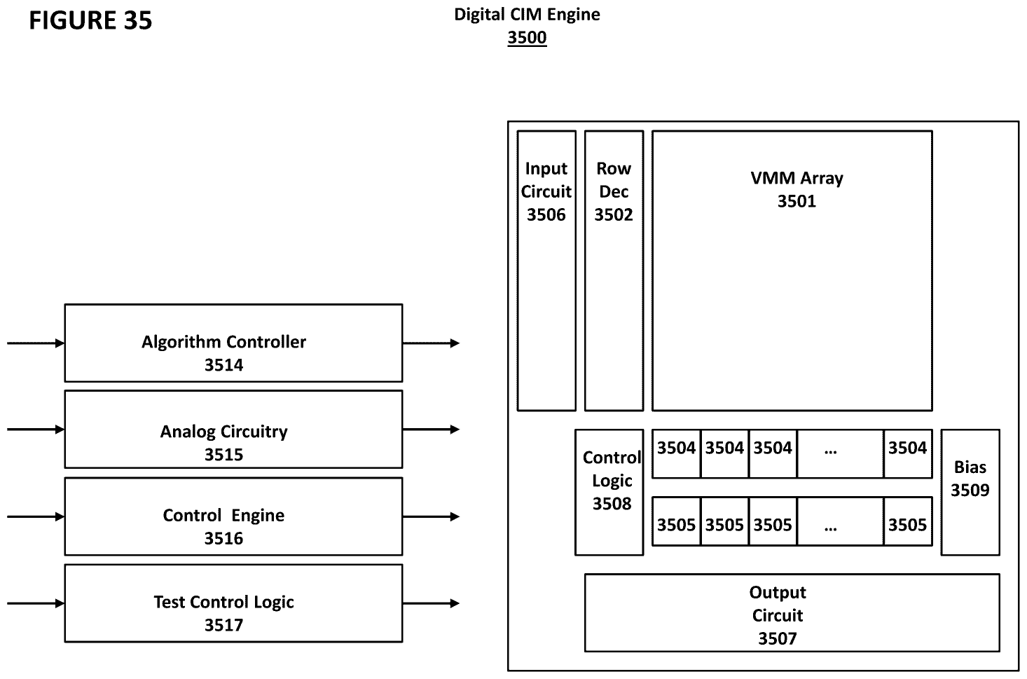

FIG. 35 depicts a block diagram of digital computation-in-memory (CIM) engine 3500. Digital CIM engine 3500 contains many, but not all, of the components contained in analog CIM engine 3400.

Digital CIM engine 3500 comprises array 3501, row decoder 3502, column decoders 3504, bit line drivers 3505 (such as bit line control circuitry for programming), input circuit 3506, output circuit 3507, control logic 3508, and bias generator 3509. Digital CIM engine 3500 further comprises algorithm controller 3514, analog circuitry 3515, control engine 3516, and test control logic 3517. Array 3501 comprises an array of non-volatile memory cells arranged into rows and columns, where the non-volatile memory cells are of the type shown in FIG. 2, 3, 4, or 5 as memory cells 210, 310, 410, or 510, respectively, or are of other types known to persons of ordinary skill in the art. In one example, the non-volatile memory cells are split-gate flash memory cells as in FIG. 2, 3, or 4. In another example, the non-volatile memory cells are stacked-gate flash memory cells as in FIG. 5. Array 3501 operates in the digital domain, where the values stored in each non-volatile memory cell is a binary value as opposed to an analog value as in analog CIM engine 3400.

The input circuit 3506 may include circuits such as a DAC, DPC, AAC, PAC, or any other type of converter. The input circuit 3506 may implement one or more of normalization, linear or non-linear up/down scaling functions, or arithmetic functions. The input circuit 3506 may implement a temperature compensation function for input levels. The input circuit 3506 may implement an activation function such as ReLU or sigmoid. Input circuit 3506 may store digital activation data to be applied as, or combined with, an input signal during a program or read operation. The digital activation data can be stored in registers. Input circuit 3506 may comprise circuits to drive the array terminals, such as CG, WL, EG, and SL lines, which may include sample-and-hold circuits and buffers. A DAC can be used to convert digital activation data into an analog input voltage to be applied to the array. Output circuit 3507 may include circuits such as an ITV, ADC, AAC, APC, or any other type of converter. Output circuit 3507 may convert array outputs into activation data. Output circuit 3507 may implement an activation function such as ReLU or sigmoid. Output circuit 3507 may implement one or more of statistic normalization, regularization, up/down scaling/gain functions, statistical rounding, or arithmetic functions (e.g., add, subtract, divide, multiply, shift, log) for neuron outputs. Output circuit 3507 may implement a temperature compensation function for neuron outputs or array outputs (such as bitline output) so as to keep power consumption of the array approximately constant or to improve precision of the array (neuron) outputs such as by keeping the IV slope approximately the same over temperature. Output circuit 3507 may comprise registers for storing output data.

In an alternative example, digital CIM engine 3500 does not utilize any analog circuitry and operates purely in the digital domain. For example, input circuit 3506 and output circuit 3507 can be formed of purely digital logic circuits that operate in the digital domain and analog circuitry 3515 can be removed.

### Hybrid System Comprising Analog Computation-in-Memory Engines, Digital Computation-in-Memory Engines, and Dynamic Weight Engines

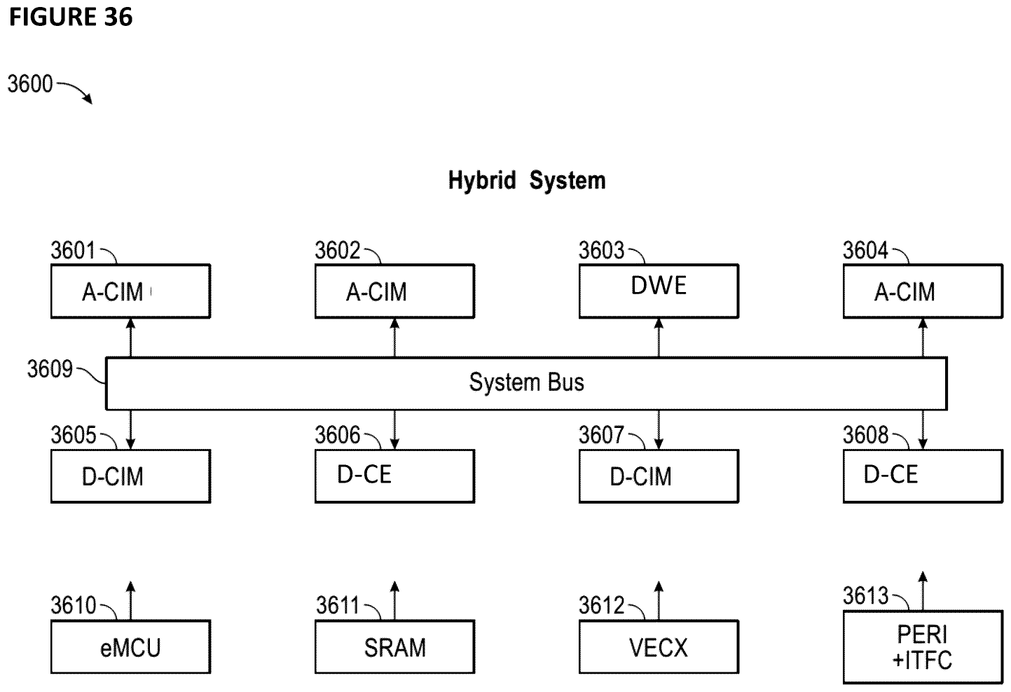

FIG. 36 depicts hybrid system 3600. Hybrid system comprises analog CIM engines 3601, 3602, and 3604; digital CIM engines 3605 and 3607; digital computation engines 3606 and 3608; dynamic weight engine 3603; and system bus 3609.

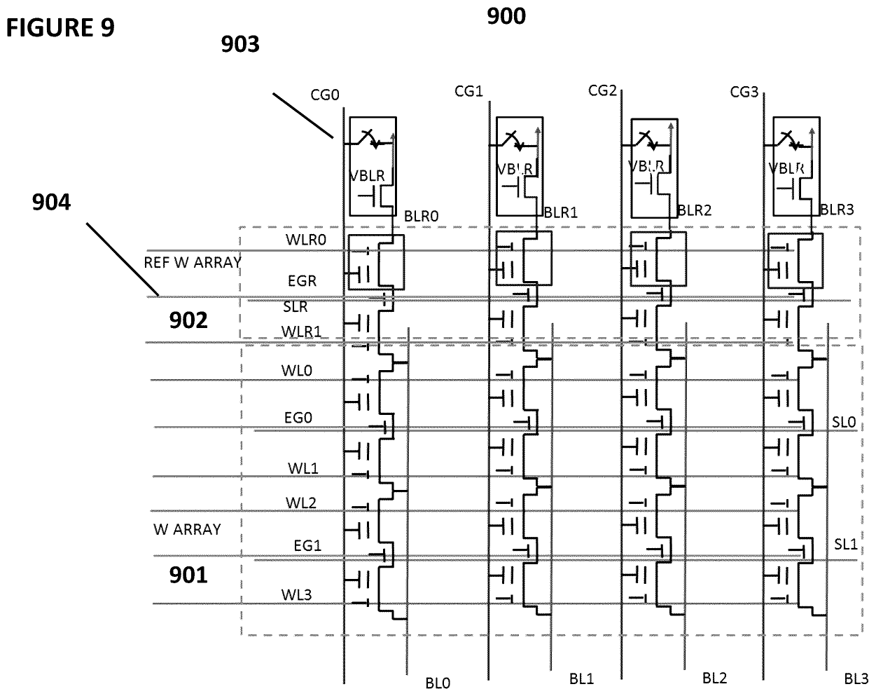

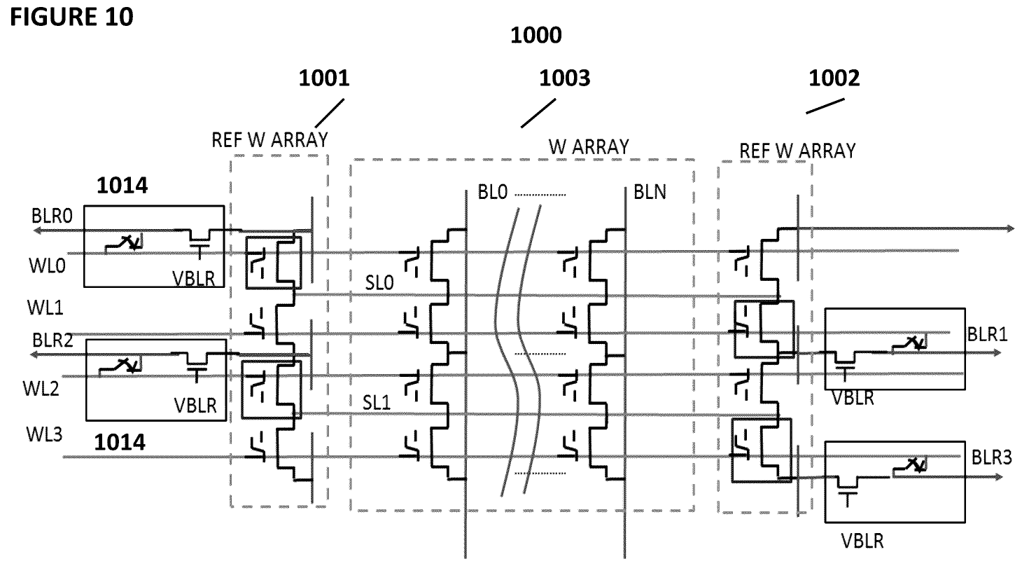

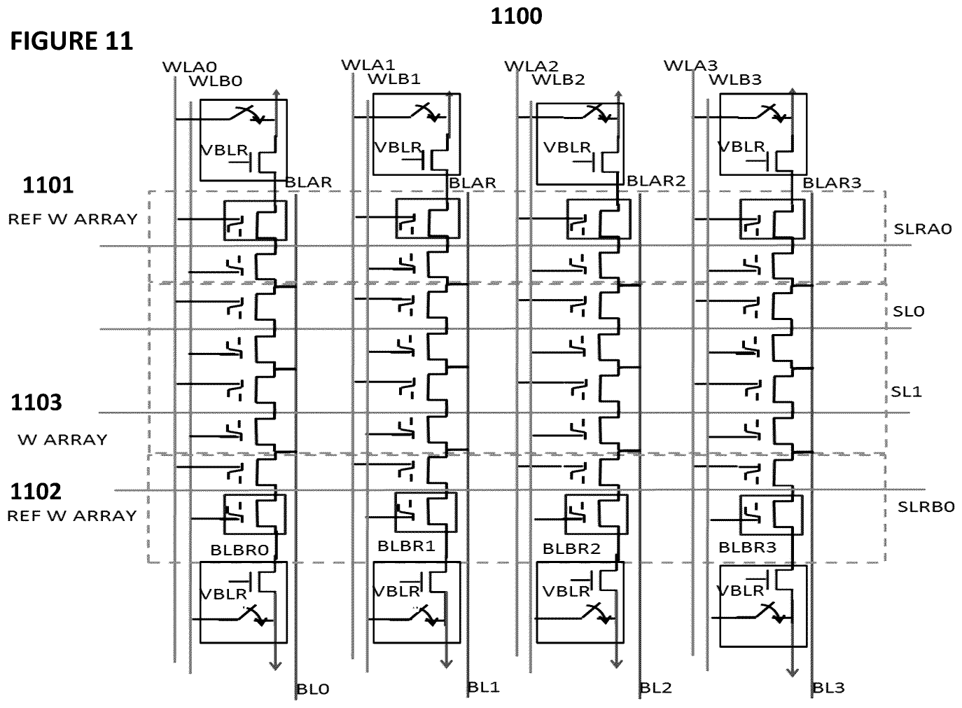

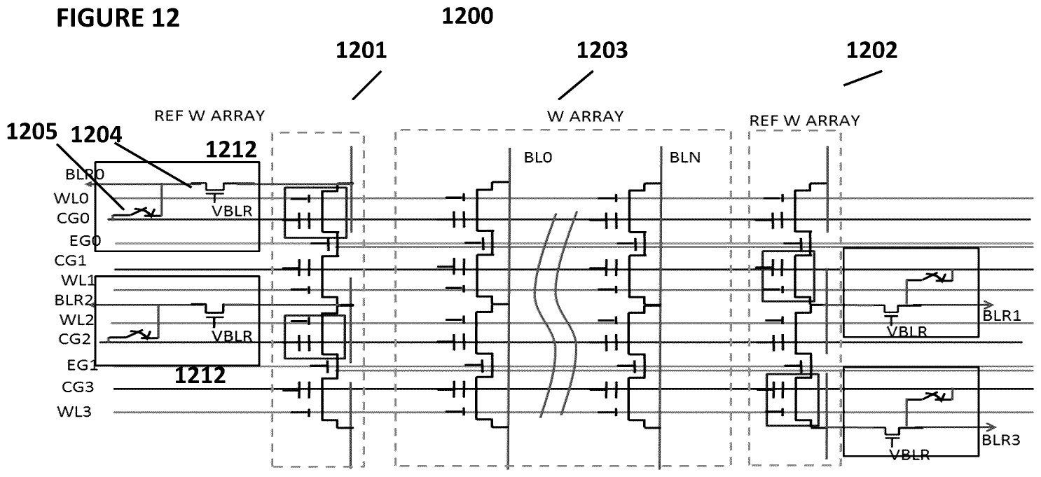

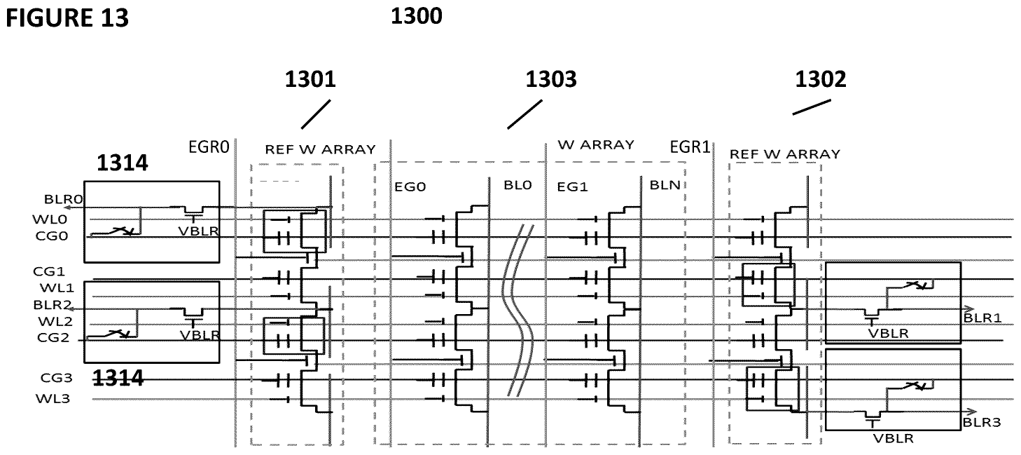

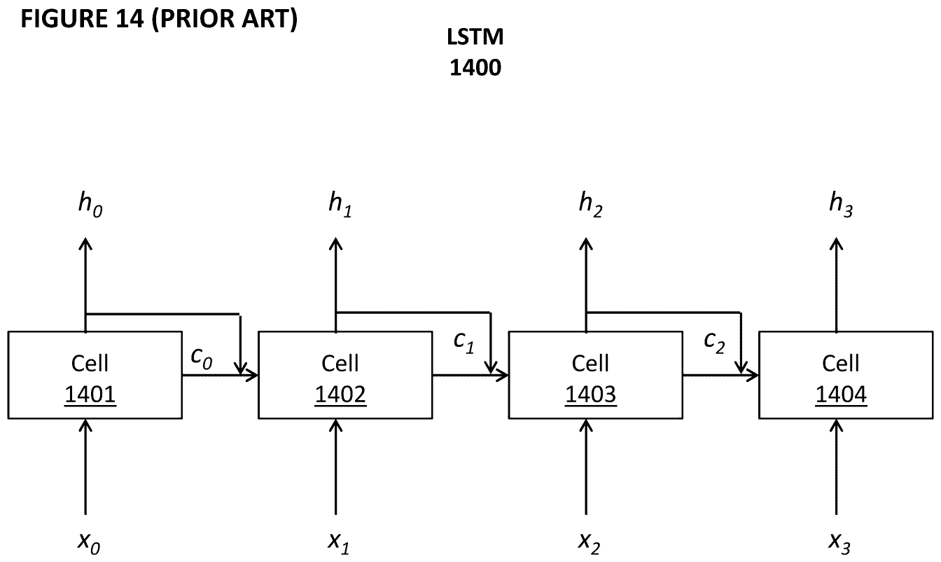

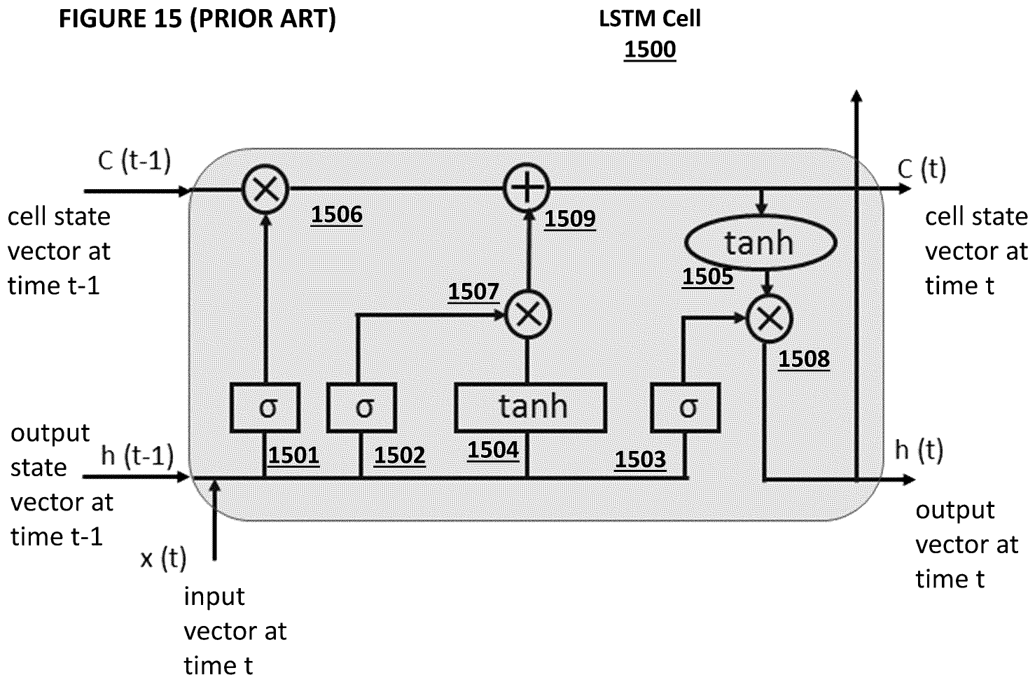

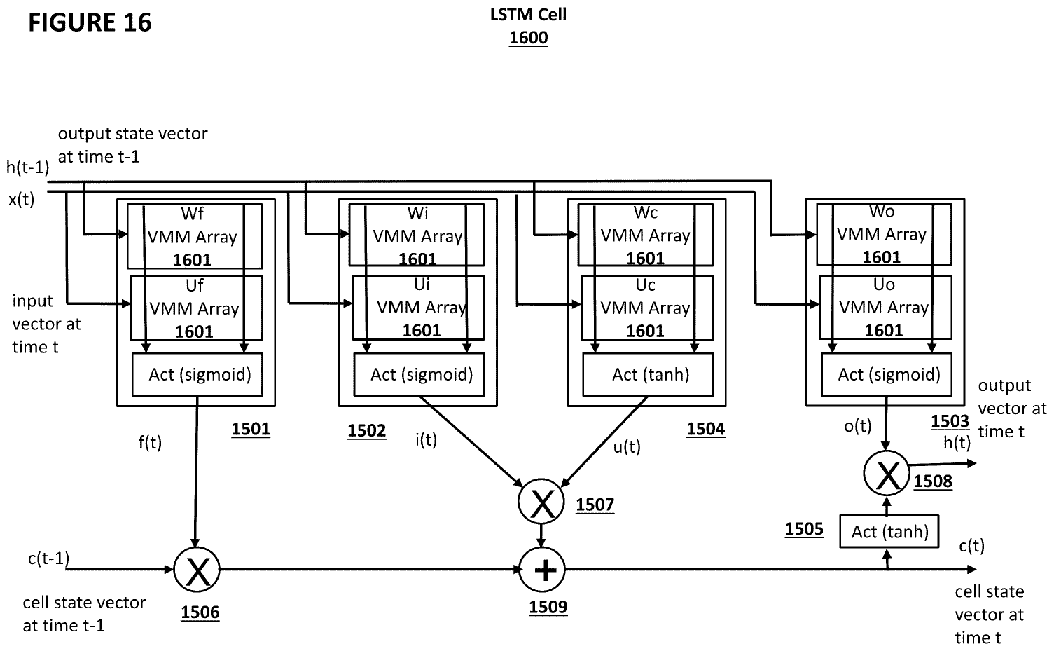

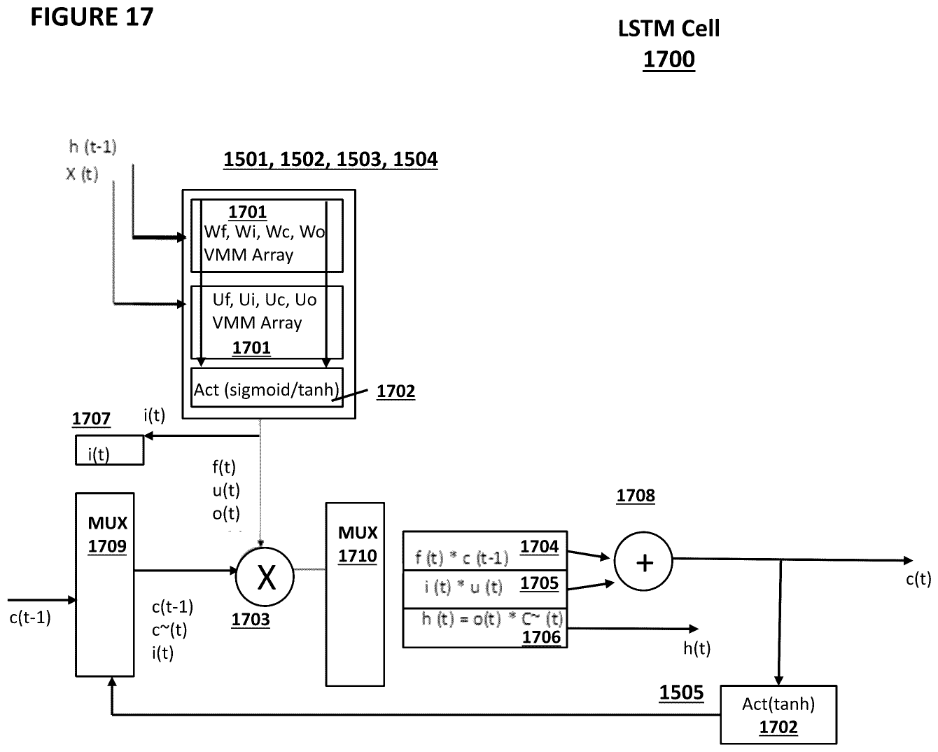

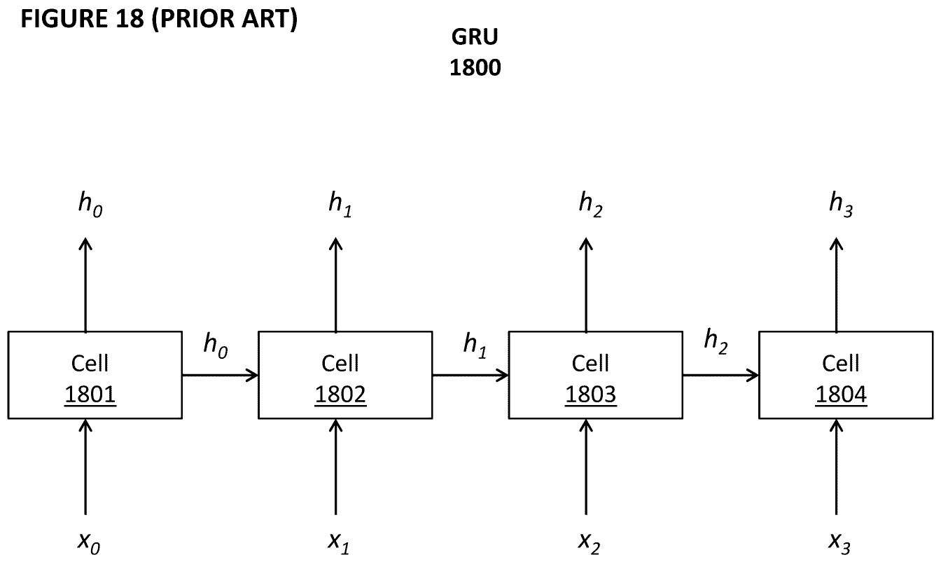

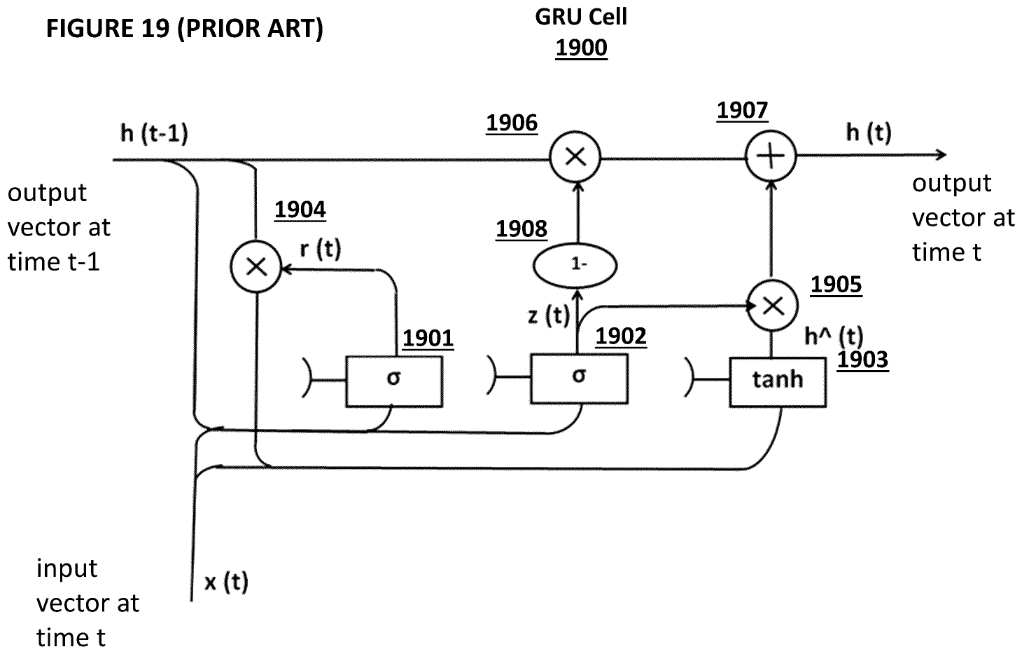

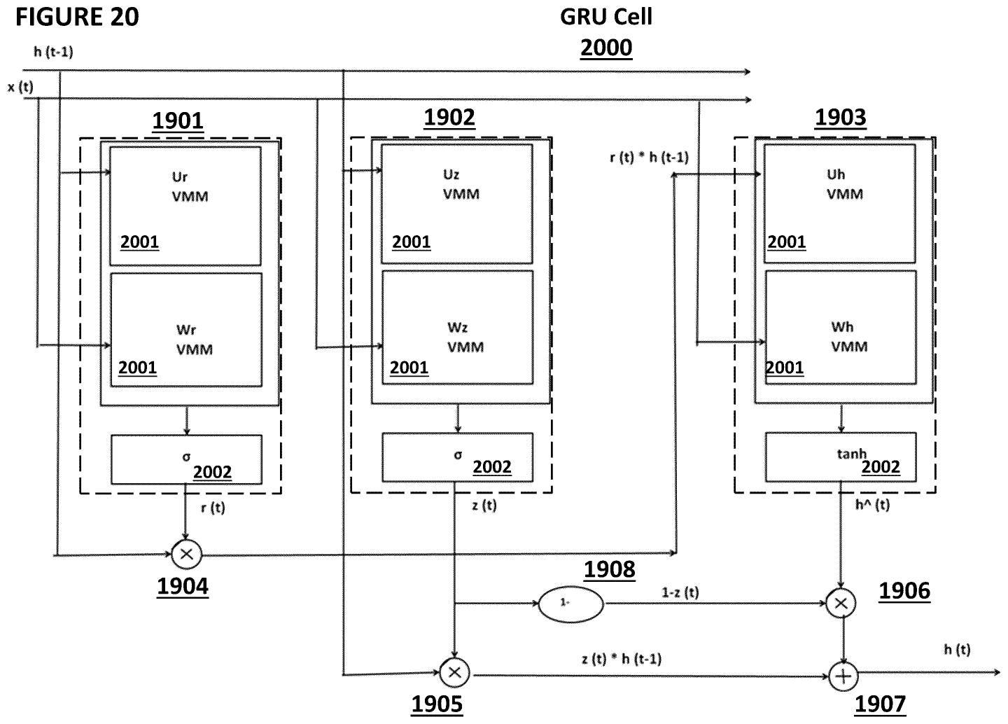

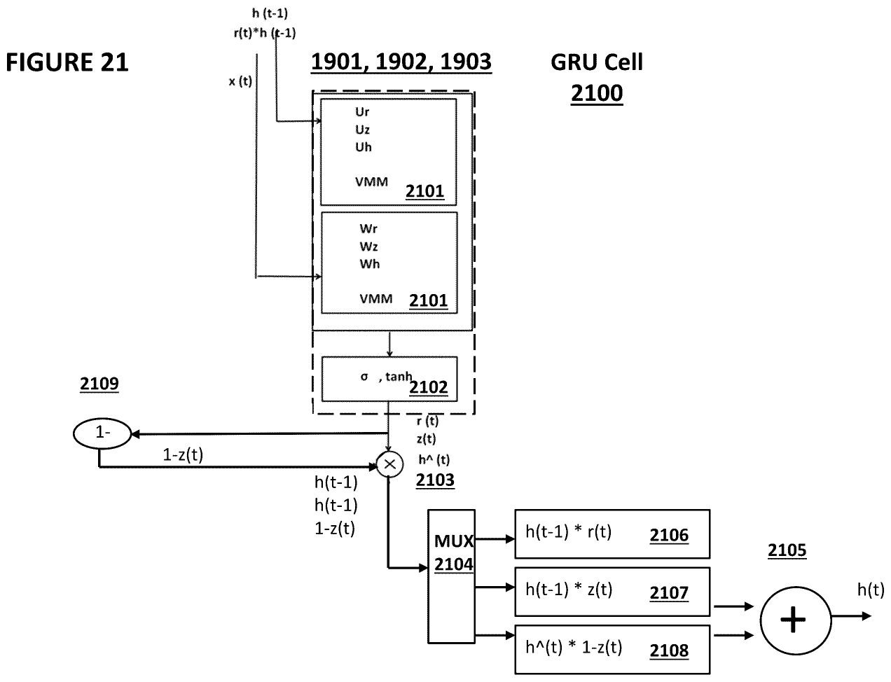

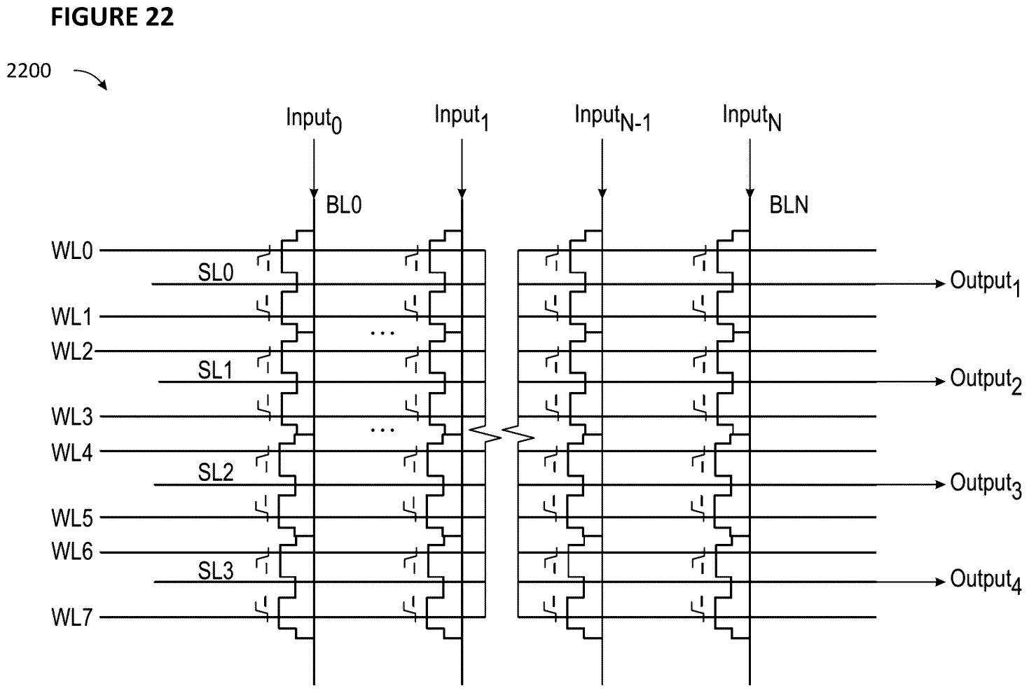

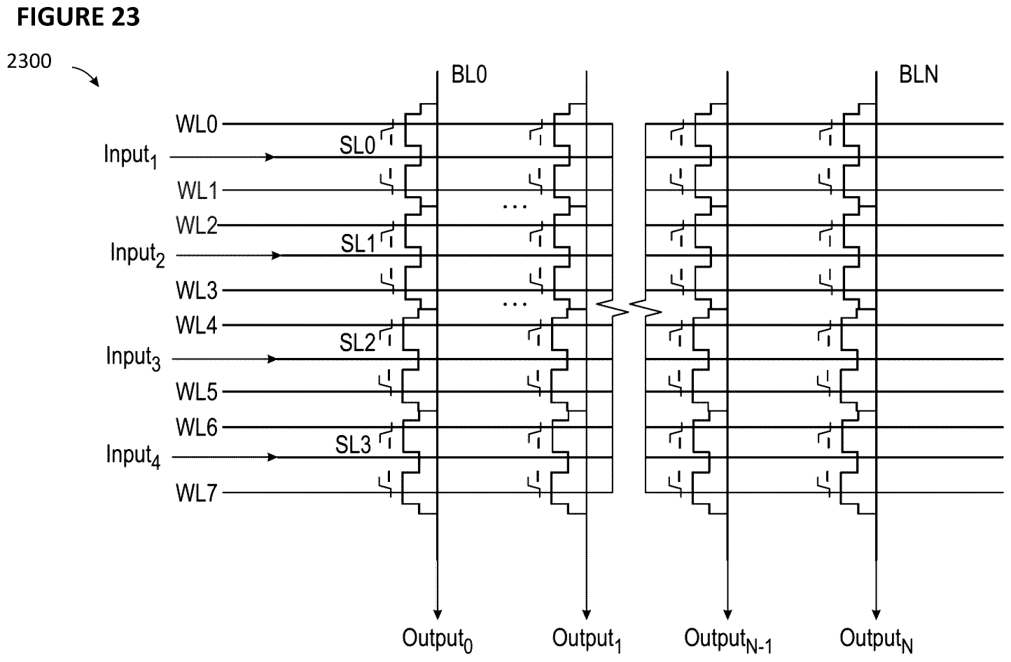

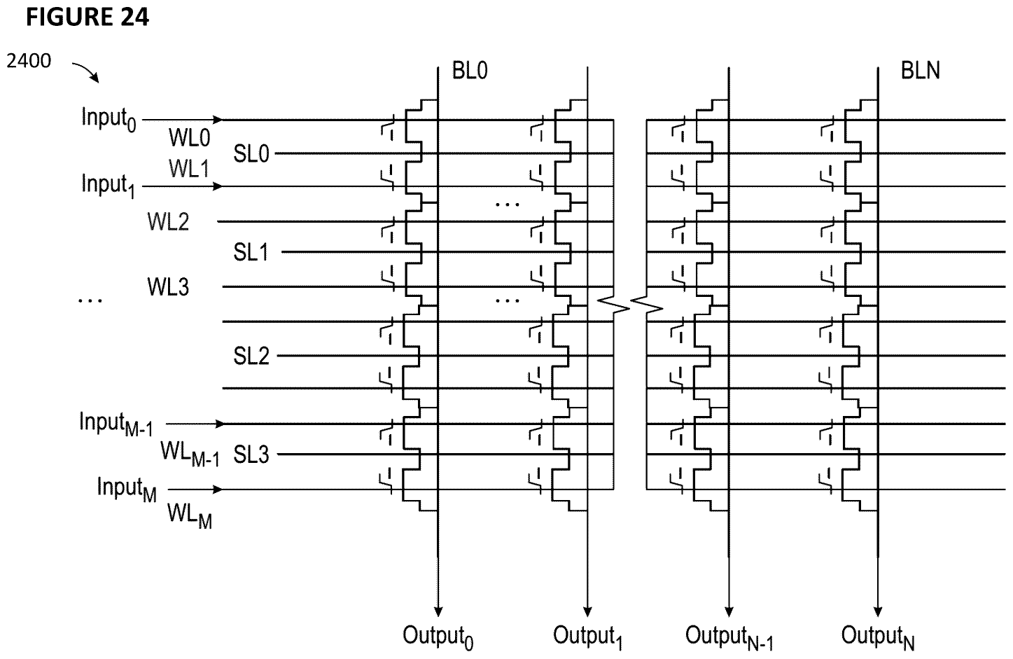

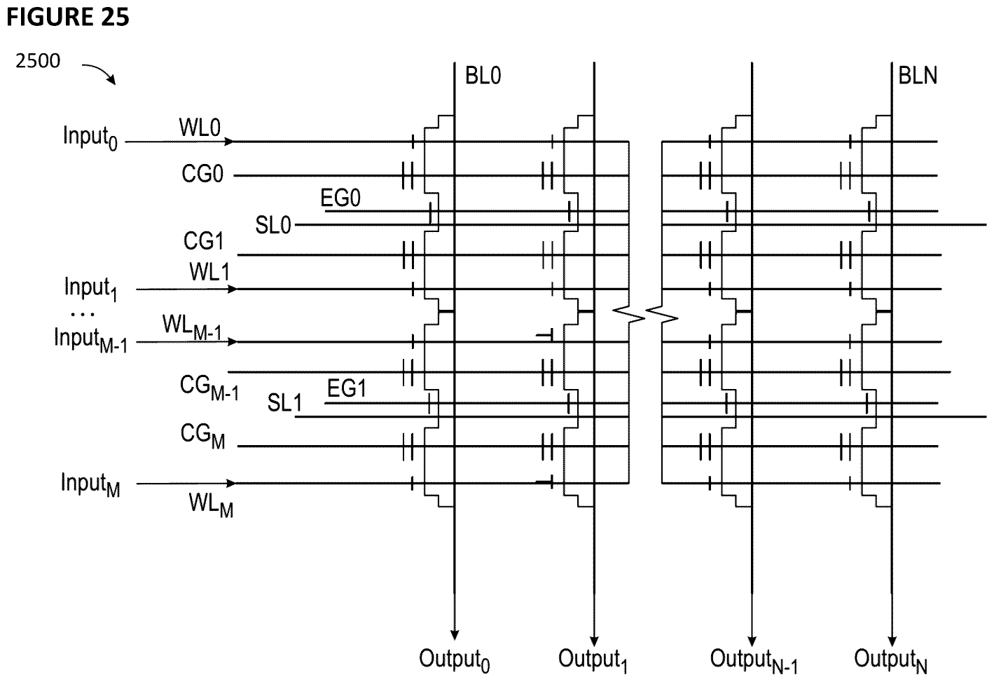

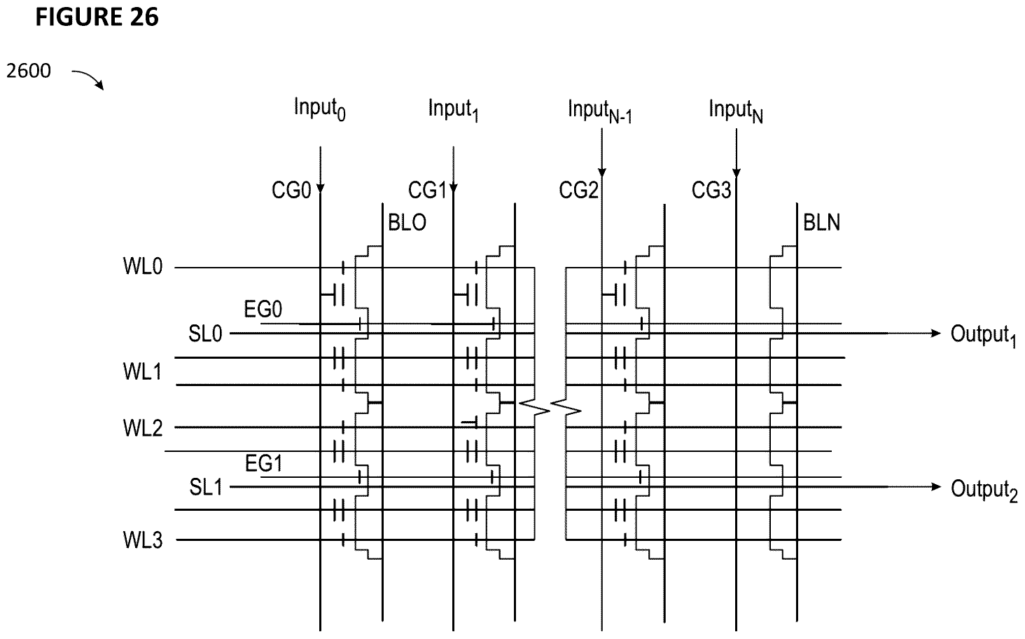

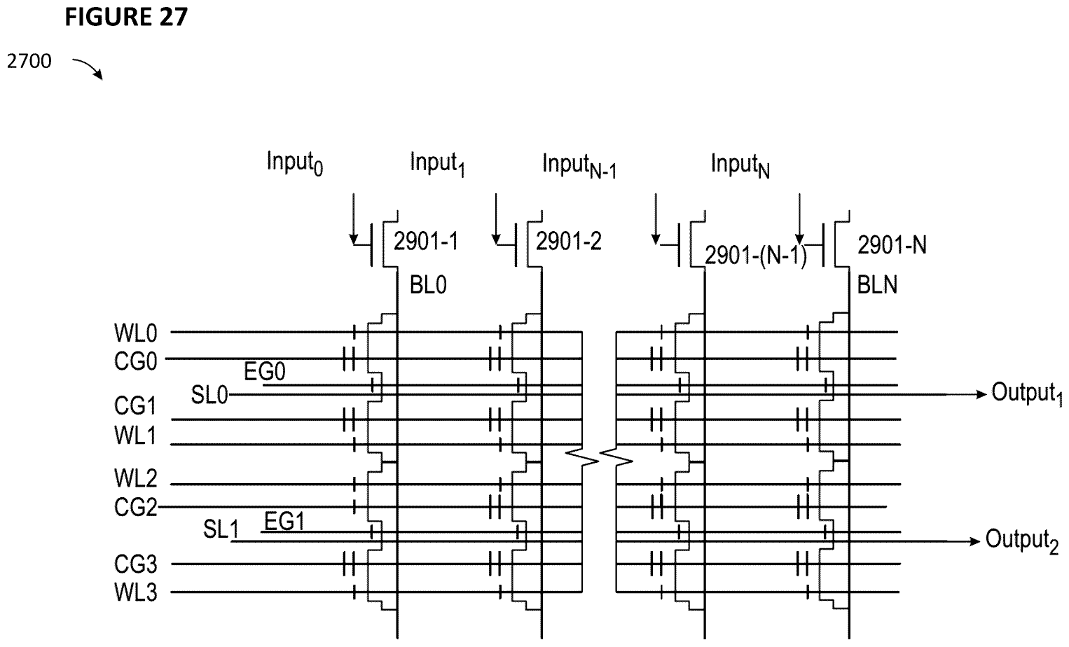

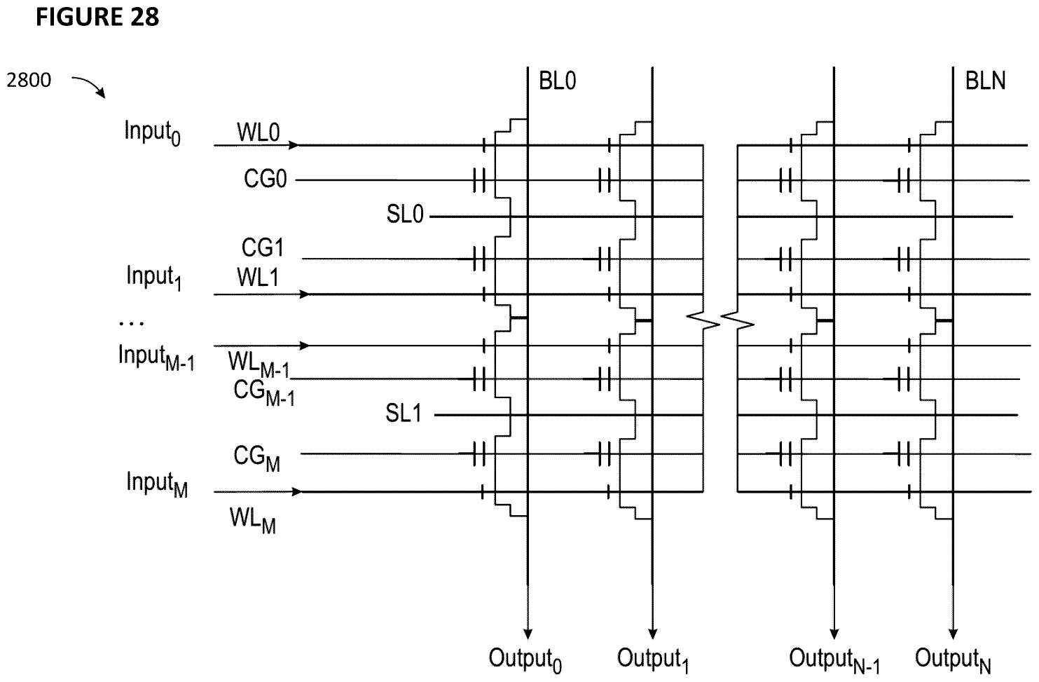

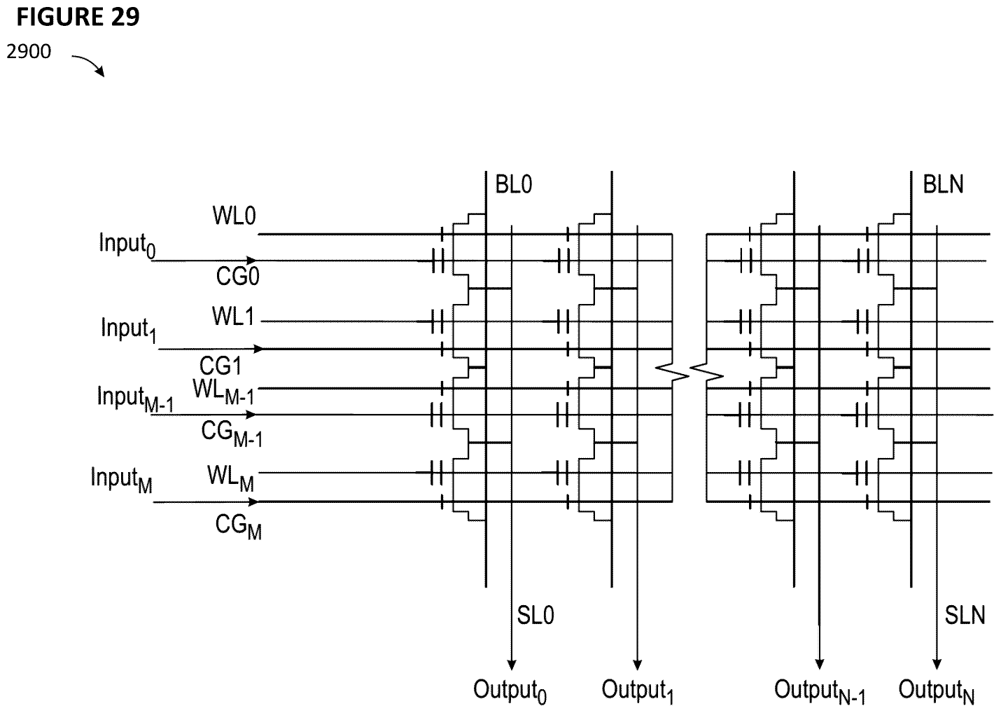

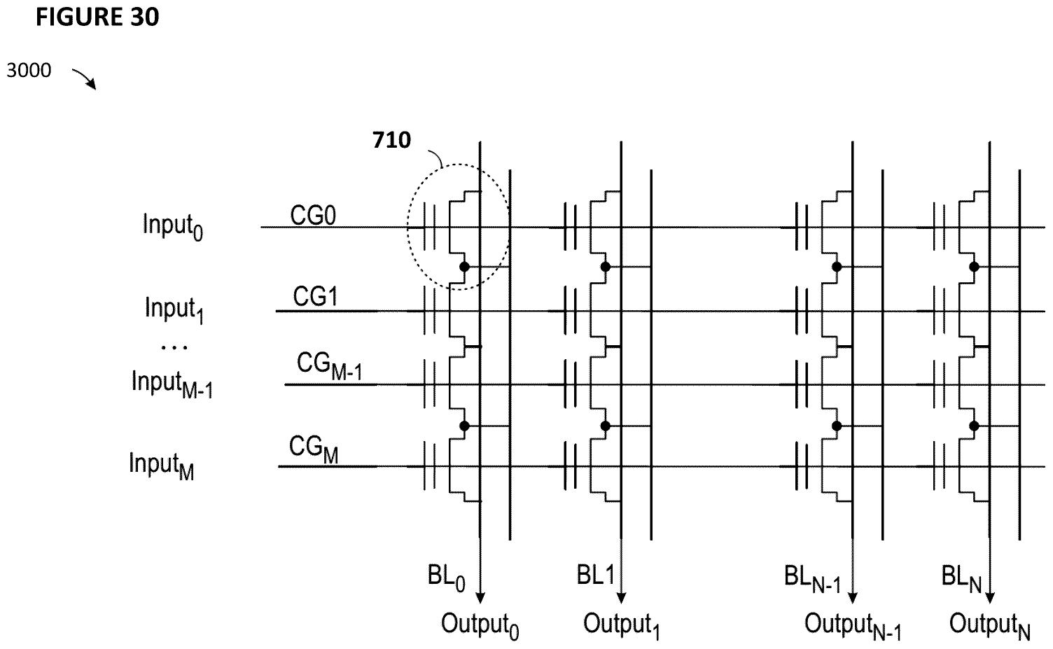

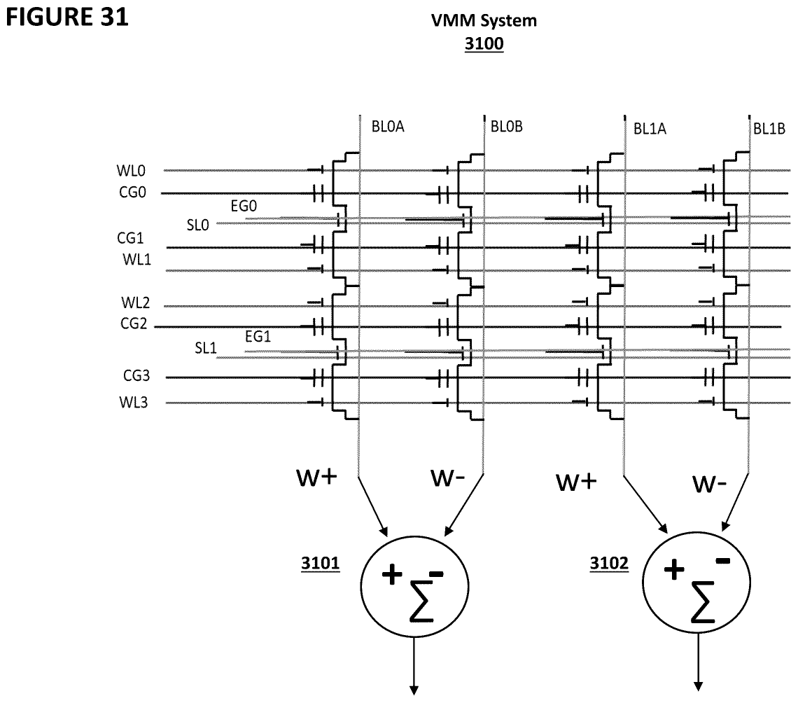

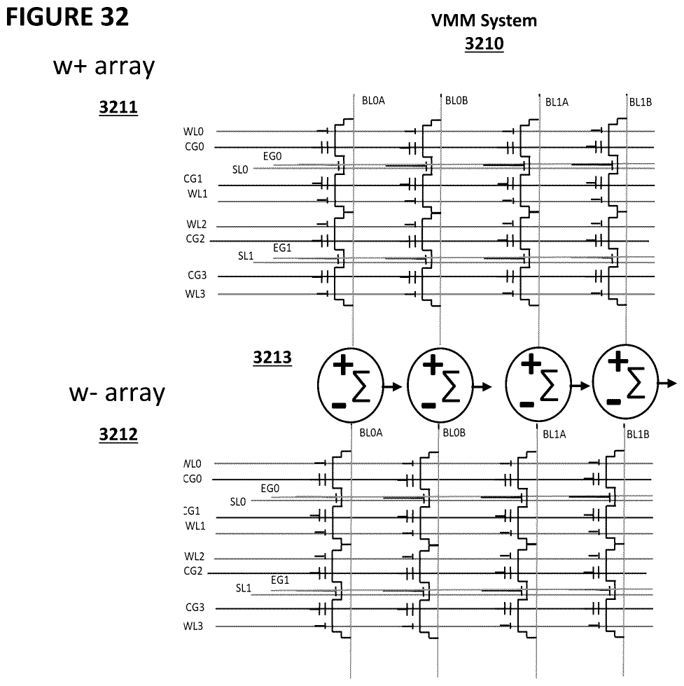

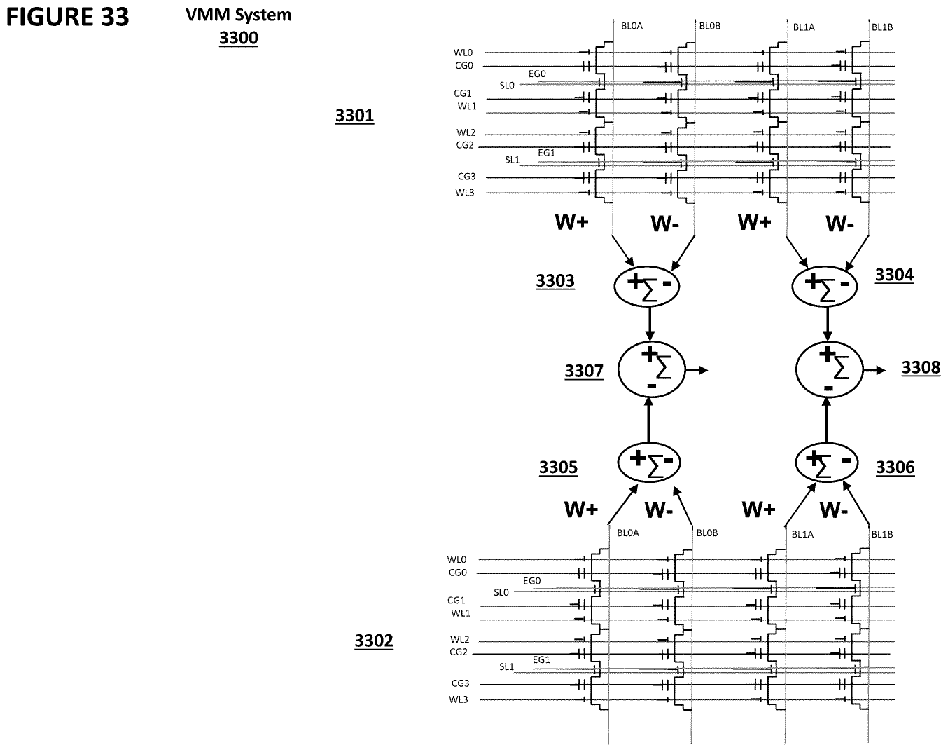

Analog CIM engines 3601, 3602, and 3604 store analog weights (e.g., N=256) in non-volatile memory cells of the respective VMM array (e.g., VMM array 3401) and perform VMM operations on those analog weights. The VMM systems described in FIGS. 9-13 and 22-33 are examples of analog CIM engines.

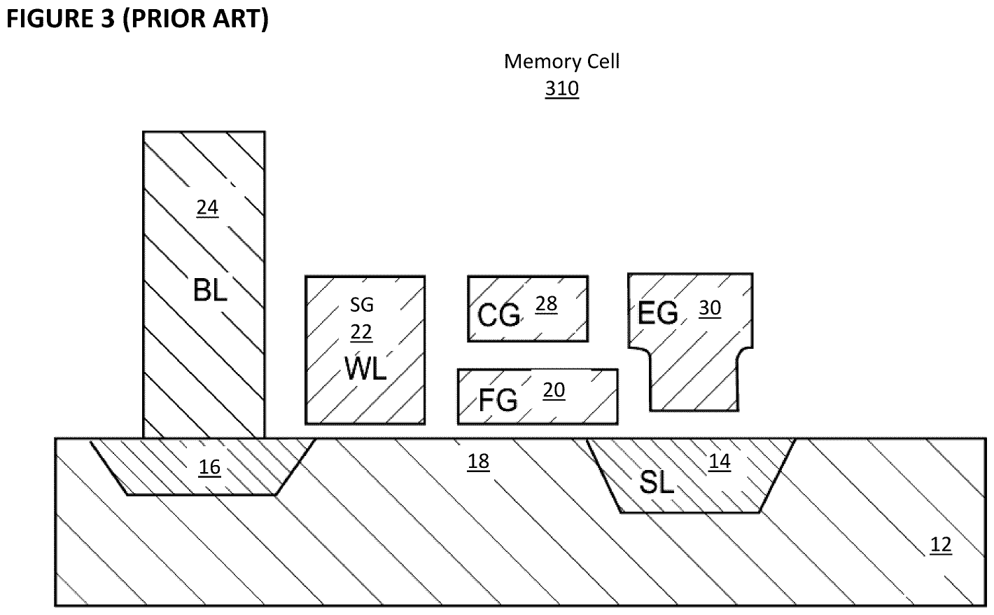

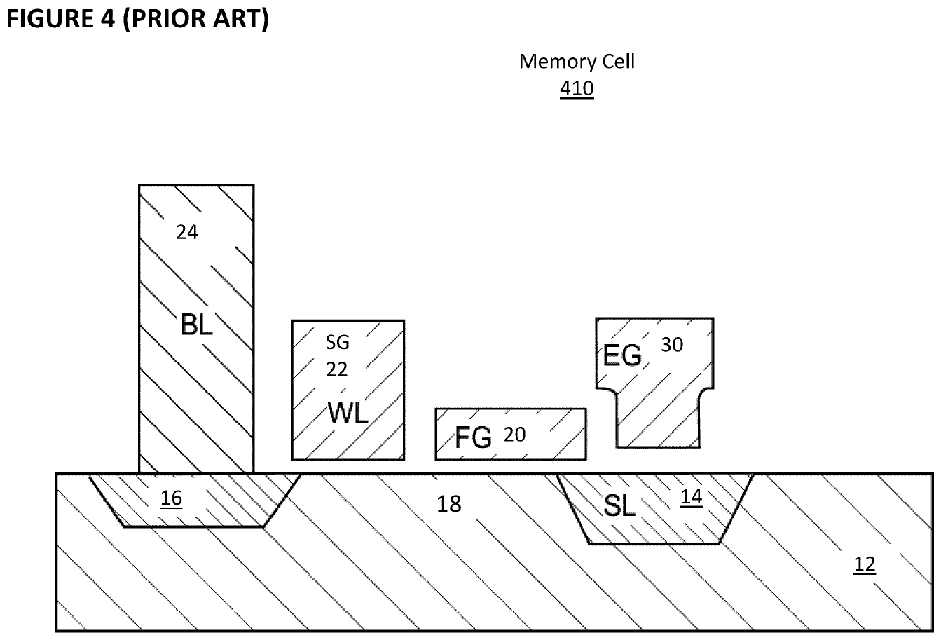

Digital computation-in-memory (CIM) engines 3605 and 3607 store digital weights (i.e., N=2) in non-volatile memory cells of the respective VMM array (e.g., VMM array 3501) and perform VMM operations on those digital weights. Alternatively, the digital CIM engines 3605 and 3607 can store digital weights in non-volatile macros or chips. Unlike analog CIM engines, digital CIM engines can utilize arrays of SRAM or DRAM cells in addition to non-volatile memory cells with floating gates such as those shown in FIGS. 2-5.

Digital computation engines 3606 and 3608 are microprocessors, digital signal processors, or other digital computation engines such as GPU (graphic processing units), TPU (Tensor processing units), dedicated MAC (multiply-add-accumulate) units, dedicated SIMD (single instruction multiple data) processor, vector extension, etc. Digital computation engines 3606 and 3608 can perform computations of integers or floating point numbers. The digital computation engines 3606 and 3608 can use the weights from the VMM array in analog CIM engines or from a digital non-volatile memory macros or chips.

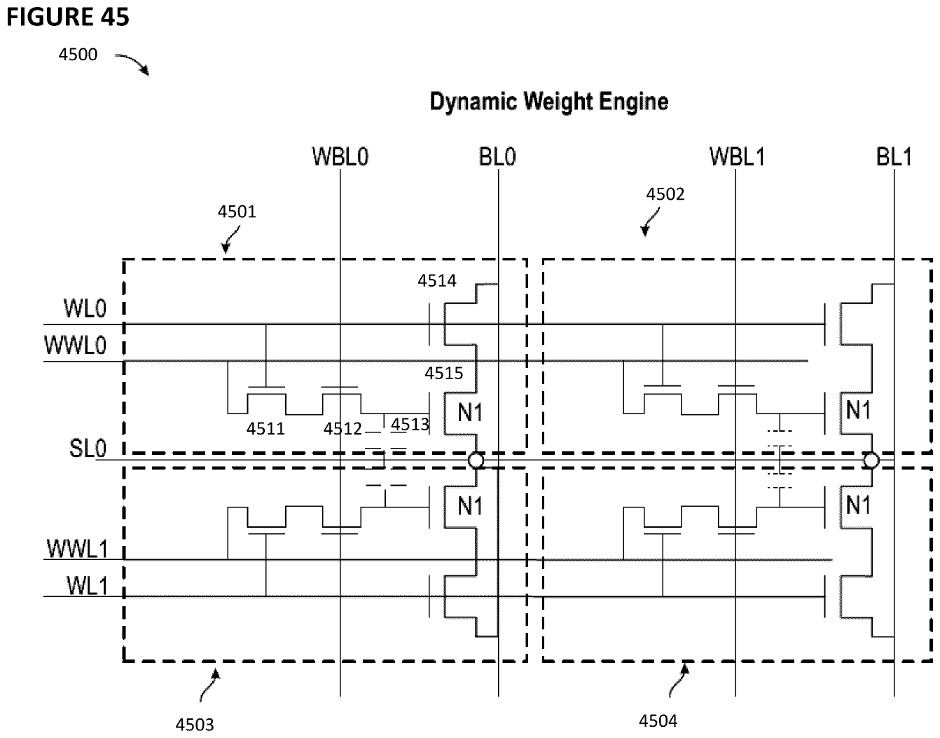

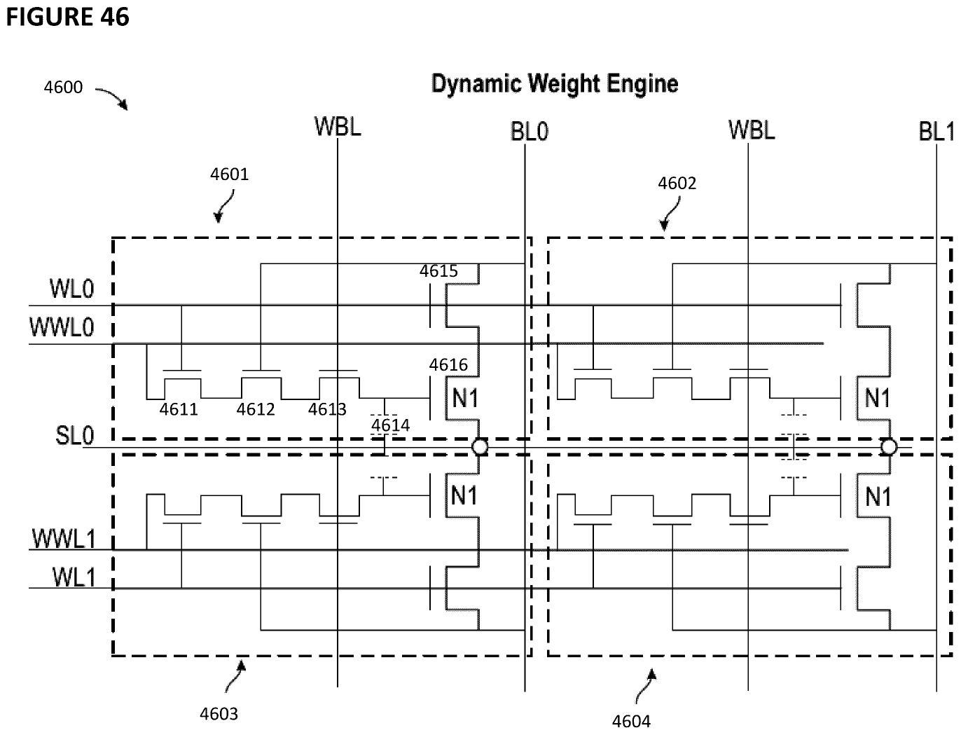

Dynamic weight engine 3603 is a device whose stored weights can be modified by changing a bias voltage or bias current without performing a separate erase or program operation. Since the weights can be modified without performing a separate erase or program operation, these weights are considered dynamic weights. The weights can be transferred from the VMM array in analog CIM engines or from a digital non-volatile memory macros or chips. Examples of dynamic weight engine 3603 are shown in FIGS. 45 and 46, in which a bias voltage is transferred into a gate of a transistor in a unit CIM array cell. The dynamic weight control and bias circuits are not shown.

Dynamic weight engine 3603, analog CIM engines 3601, 3602, and 3604, digital CIM engines 3605 and 3607, and digital computation engines 3606 and 3608 are coupled to system bus 3609, which enables all coupled devices to communicate with one another.

Microcontroller 3610, SRAM 3611, vector register 3612, and peripheral control and interface logic 3613 assist in certain functions and operations (such as controlling the access to SRAM 3611, controlling the data flow of various computation engines, controlling the communication between the internal system bus 3609 and an external bus, performing activation functions, performing read, erase, and program operations on non-volatile memory (NVM) or volatile memory (VM), or performing weight transfer between computation engines, without limitation) in hybrid system 3600.

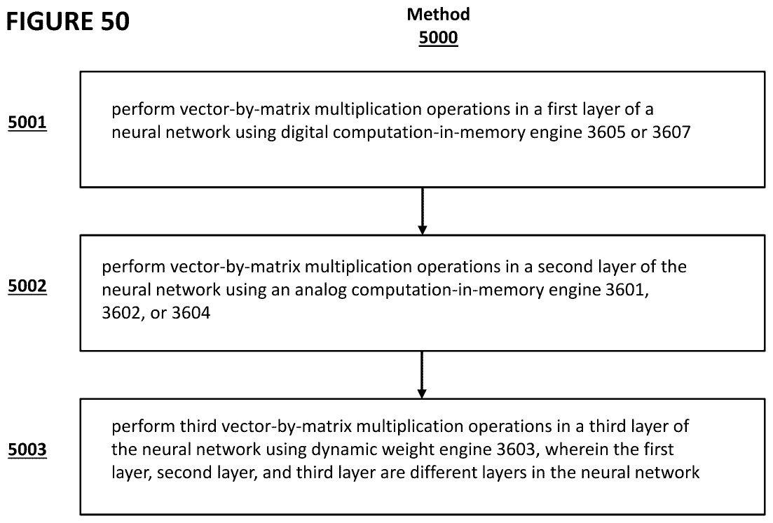

FIG. 50 depicts an example method that can be performed by hybrid system 3600. First, the system performs vector-by-matrix multiplication operations in a first layer of a neural network using digital computation-in-memory engine 3605 or 3607 (5001). Second, the system performs vector-by-matrix multiplication operations in a second layer different than the first layer of the neural network using analog computation-in-memory engine 3601, 3602, or 3604 (5002). Optionally, the system transfers dynamic weights from dynamic weight engine 3603 to one or more of the analog computation-in-memory engine 3601, 3602, or 3604 and/or the digital computation-in-memory engine 3605 or 3607 (5003). Optionally, the system stores the dynamic weights in the analog computation-in-memory engine 3601, 3602, or 3604.

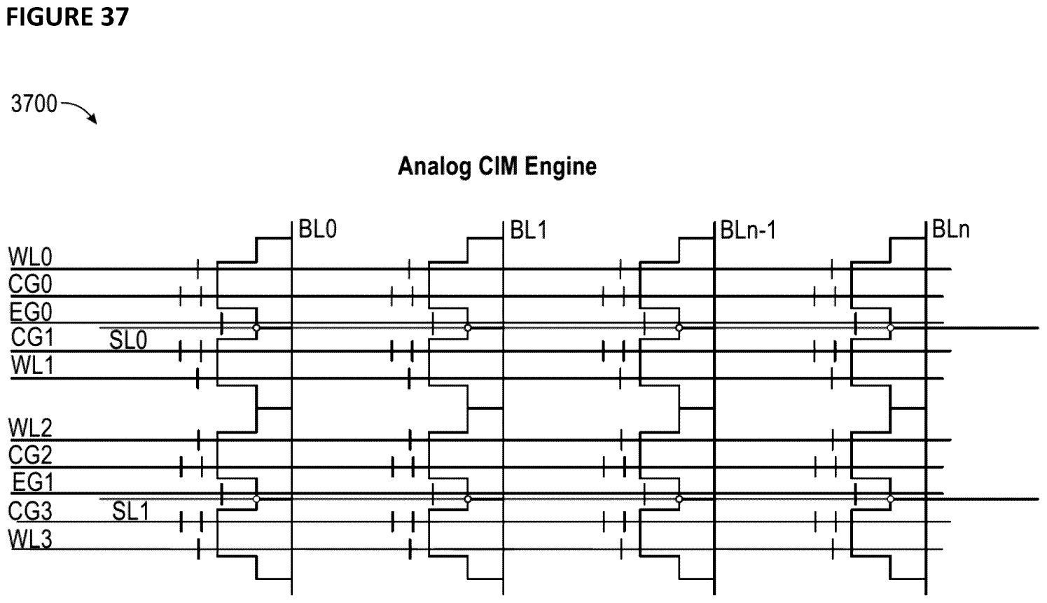

FIG. 37 depicts a portion of an example of an analog CIM engine 3700. Here, two rows and four columns of non-volatile memory cells are shown. The memory cells operate in the sub-threshold region and can store analog weights. An activation input is provided to each selected row on the word line or control gate line, the memory cells in that row multiply those activation inputs by the stored analog weights and output a current representing that product in the bit line coupled to the column of each cell. Current is then summed up along the bitline (output line). The array output current is then converted by ADC circuits (not shown) to produce digital output bits. The activation input can be provided as a pulse width (PW), as the output of a fixed bias 1-bit digital-to-analog converter, or as the output of an n-bit DAC. Other examples of a portions of an analog CIM engine are shown in FIGS. 9-13 and 22-33.

Portion of an analog CIM engine 3700 also can be used as an analog memory weight storage. In that event, a word of memory cells (e.g., 64 or 128 cells from a selected row) are selected and the output digital output bits from the ADC represents the weight values stored by the portion of analog CIM engine 3700.

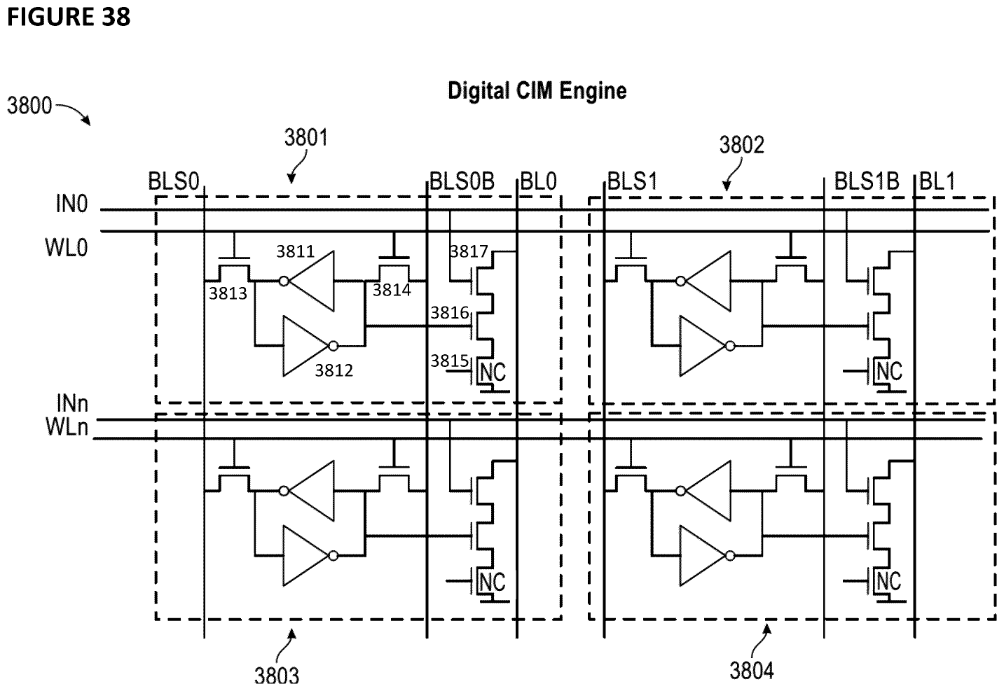

FIG. 38 depicts a portion of an example digital CIM engine 3800. Portion of digital CIM engine 3800 comprises an array of current-based CIM SRAM memory cells 3801, 3802, 3803, and 3804 arranged into rows and columns. CIM SRAM memory cell 3801 will be described in detail, and it is to be understood that the other CIM SRAM memory cells 3801 have the same design. In CIM SRAM memory cell 3801, if the weight stored in the SRAM is a “1,” then NMOS transistor 3816 is turned on, and the current NC passes from transistor 3815 to transistor 3817 toward bitline BL0. If the weight stored in the SRAM is a “0,” then NMOS transistor 3816 is turned off, and the current NC is blocked from passing from transistor 3815 to transistor 3817 toward the bitline BL0. The current NC is the effective value of the stored weight in a CIM SRAM cell.

During operation of the digital CIM engine, an input is applied to input line IN0. SRAM memory cell 3801 performs a multiplication of the input on IN0 with the stored weight. If IN0 is a “1,” then NMOS transistor 3817 is turned on to pass the current NC (representing stored weight value) to the bitline BL0, and if IN0 is a “0,” then NMOS transistor 3817 is turned off and no current NC is passed to the bitline BL0.

If the stored weight is a “1” and if the input on the input line is a “1”, then bit line BL0 will receive the current NC because NMOS transistors 3815, 3816, and 3817 are all on. If the stored weight is a “0” or if the input on the input line is a “0,” then bit line BL0 will be disconnected from the current NC and will not contain any current attributable to SRAM memory cell 3801.

CIM SRAM memory cells 3802, 3803, and 3804 and other CIM SRAM memory cells in the digital CIM engine operate in the same manner as CIM SRAM memory cell 3801.

The bit lines of the digital CIM engine, such as BL0 and BL1, will sum the currents of all CIM SRAM memory cells connected to them, meaning that BL0 will contain the sum of all currents (all NC currents with weights=“1”) of all CIM SRAM memory cells in column 0, BL1 will contain the sum of all currents of all CIM SRAM memory cells in column 1, and so forth. This current can be converted into digital output bits by an ADC circuit or multi-bit sense amplifier circuit.

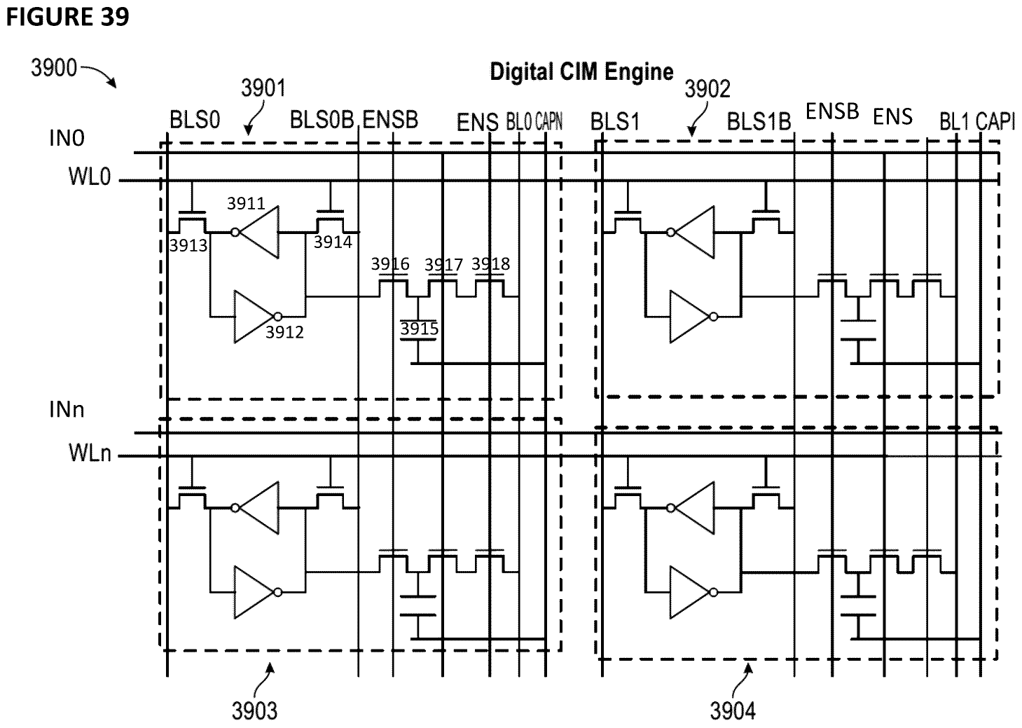

FIG. 39 depicts a portion of another example digital CIM engine 3900. Portion of digital CIM engine 3900 comprises an array of charge-based CIMSRAM memory cells 3901, 3902, 3903, and 3904 arranged into rows and columns.

CIM SRAM memory cell 3901 is representative of CIM SRAM memory cells 3902, 3903, and 3904 and other CIM SRAM memory cells in the digital CIM engine and its operation will now be described. SRAM memory cell 3901 comprises inverters 3911 and 3912 forming a latch; NMOS transistors 3913, 3914, 3916, 3917, and 3918; and capacitor 3915. An amount of charge (representing a weight value), Q, equal to C (the capacitance value of the capacitor) * Vdds (which is the supply voltage for the SRAM memory cell) is stored on the capacitor 3915 in an SRAM cell. The latch formed by inverters 3911 and 3912 can store a value of “0” or “1,” (=output of the inverter 3912), where “0” means zero charge and “1” means Q charge, which is the effective weight for SRAM memory cell 3901. When the output of the inverter 3912 is ‘0’, meaning=ground (0V), the capacitor 3915 will be charged to ground through in the transistor 3916, hence Q=0 (representing '0 weight). When the output of the inverter 3912 is ‘1’, e.g., =Vdds, the capacitor 3915 will be charged to Vdds through in the transistor 3916, hence Q =C*Vdds (representing “1” weight). The stored charge is transferred to the bitline BL0 when the transistor 3916 is off (ENSB=“0”), transistor 3917 is on (input IN0=“1”) and transistor 3918 is on (ENS=“1”). For a weight of “1,” a charge Q (=C*Vdss) will be transferred to the bitline BL0 if the input IN0=‘1’ (meaning the transistor 3917 is on).

The weight is stored in SRAM memory cell 3901 through a write operation. During the write operation, word line WL0 is asserted, which turns on NMOS transistors 3913 and 3914. A “1” is stored in the latch by driving BLS0B high and BLS0 low, and a “0” is stored in the latch by driving BLS0 high and BLS0B low.

During an inference or read operation of the digital CIM engine, an input is applied to input line IN0, and ENSB is asserted. SRAM memory cell 3901 performs a multiplication of the input on IN0 with the stored weight. If IN0 is a “1,” then NMOS transistor 3917 is turned on, and if WLN0 is a “0,” then NMOS transistor 3917 is turned off.

If the stored weight is a “1” and if the input INx on the input line is a “1”, then bit line BL0 will receive the charge of the capacitor 3915 because NMOS transistors 3916 is off, and transistors 3917 and 3918 are on. If the stored weight is a “0” or if the input on the input line INx0 is a “0,” then bit line BL0 will receive a 0 charge and will not contain any charge component attributable to SRAM memory cell 3801.

SRAM memory cells 3902, 3903, and 3904 and other SRAM memory cells in the digital CIM engine operate in the same manner as SRAM memory cell 3901.

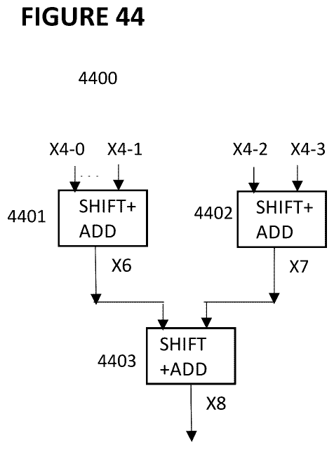

The bit lines of the digital CIM engine, such as BL0 and BL1, will sum the charges of all SRAM memory cells connected to them, meaning that BL0 will contain the sum of all charges output by all SRAM memory cells in column 0, BL1 will contain the sum of all charges output by all SRAM memory cells in column 1, and so forth. This summed charge can be converted into digital output bits by an ADC circuit such as those shown in FIGS. 44 and 46 below.

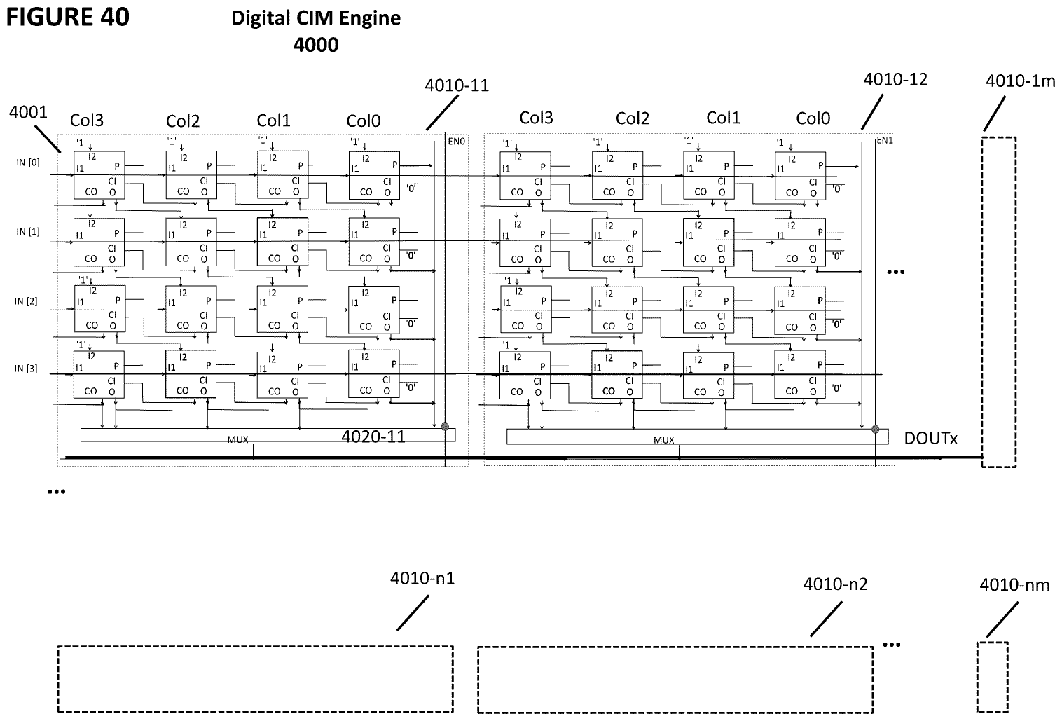

FIG. 40 depicts a portion of another example digital CIM engine 4000. Portion of digital CIM engine 4000 comprises sub-arrays of CIM digital cells, where each CIM digital cell stores a weight, w, of 1-bit. In this example, sub-arrays 4010-11 and 4010-12 are shown in detail. In the horizontal direction, digital CIM engine 4000 comprises m sub-arrays (such as sub-arrays 4010-11, 4010-12, . . . , 4010-1m in row 1). In the vertical direction, digital CIM engine 4000 comprises n sub-arrays (such as sub-arrays 4010-11, . . . , 4010-n1 in column 1).

Sub-array 4010-11 will now be described as an example. The discussion as to sub-array 4010-11 applies to the other sub-arrays as well. Sub-array 4010-11 comprises an array of CIM digital cells, such as CIM digital cell 4001, arranged into rows and columns. In this example, sub-array 4010-11 comprises four rows and four columns of CIM digital cells, but it is to be understood that sub-array 4010-11 and the other sub-arrays each could instead comprise any number of rows and columns according to the same principles discussed here, such as 8 rows and 8 columns to accommodate an 8-bit input and an 8-bit weight (meaning 1 bit is stored in each of 8 CIM digital cells, together storing an 8-bit weight) yielding a 16-bit output (since 8-bit input multiplied with 8-bit weight yields 16-bit output). In this example, sub-array 4010-11 implements a 4-bit input multiplied by a 4-bit weight, the output DOUT [7:0]=IN [3:0]* W [3:0], with each row of 4 CIM digital cells storing 4 weight W [3:0], and four rows storing the same weight W [3:0]. MUX block is used to enable the output from each sub-array 4010x into the main output bus DOUTx.

Digital CIM engine 4000 receives inputs for a plurality of rows. In this example, sub-array 4010-11 receives inputs IN[0], IN[1], IN[2], and IN[3] on its four rows. The 4-bit input is to multiplied with 4-bit weight W [3:0] stored in the each row. Each digital cell, such as digital cell 4001, receives an input on its port I1, multiplies the input by a 1-bit weight value (W) stored in the digital cell, and adds the resulting product with any data received on its port I2 from a digital cell located in a row above it along with any carryover bit received on its port CI from a neighboring digital cell located to its right in the same row. In the example shown, the left-most column (Col3) represents the most significant bit of the weight, the column to its right (Col2) represents the next most significant bit of the weight, the next column to the right (Col1) represents the next most significant bit of the weight, and the last column (Col0) represents the least significant bit of the weight.

Each CIM digital cell such as CIM digital cell 4001 comprises a memory device such as an SRAM cell, latch, or register for storing a weight, W. Each digital cell such as CIM digital cell 4001 also comprises digital multiply and add logic. Inputs are received in digital form by each row of digital devices in the I1 port of each CIM digital cell. The input received on port I1 is multiplied by the weight stored in the SRAM of the CIM digital cell and the results are then added and output on a column-by-column basis. The output (O) of a particular CIM digital cell is provided as an input (I2) to the CIM digital cell located below that particular CIM digital cell in the same column, and the carry output (CO) from a particular CIM digital cell is provided as a carry input (CI) input to the CIM digital cell located to its left in the same row, as that cell represents a more significant bit than the particular CIM digital cell.

Multiplexor block 4020-11 is used to enable the output from sub-array 4010-11 into the main output bus DOUTx in response to enable signal EN0. The other sub-arrays have similar multiplexor blocks.

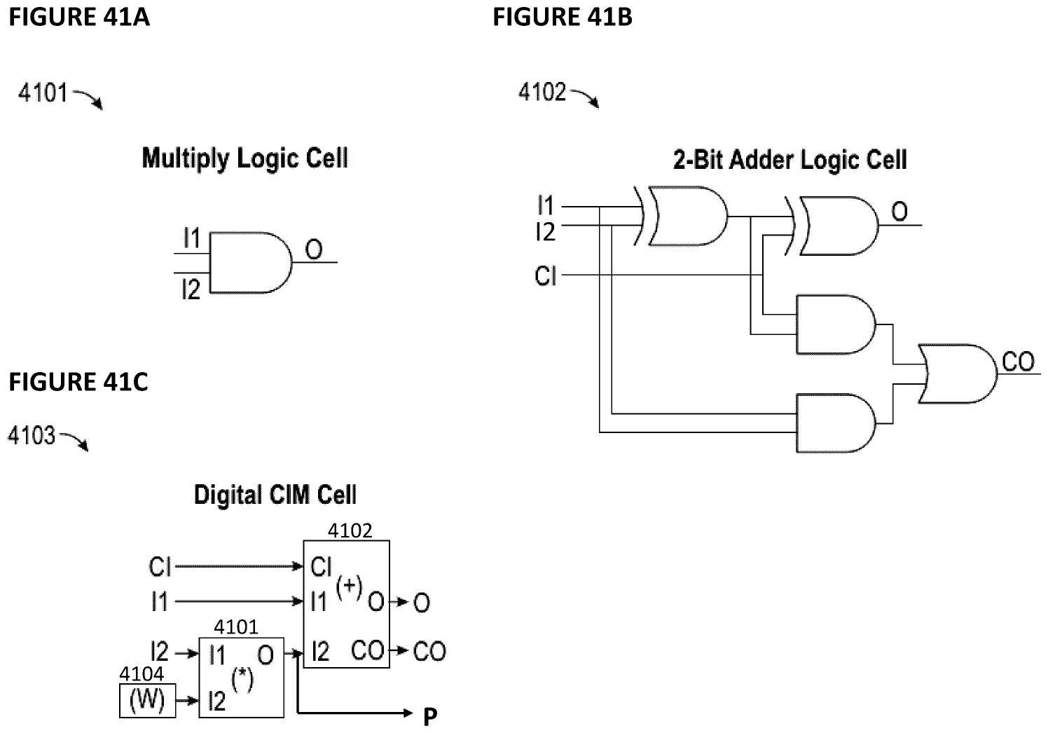

FIGS. 41A, 41B, and 41C depict example components that can be used in each CIM digital cell of FIG. 40 such as CIM digital cell 4001.

With reference to FIG. 41A, multiply logic cell 4101 receives two inputs, I1 and I2, and outputs their product, O, according to the truth table shown in Table 9:

TABLE NO 9
Truth Table for Multiply Logic Cell 4101

| I1 | I2 | O |
|---|---|---|
| 0 | 0 | 0 |
| 0 | 1 | 0 |
| 1 | 0 | 0 |
| 1 | 1 | 1 |

With reference to FIG. 41B, 2-bit adder logic cell 4102 receives inputs I1 and I2, and carry input CI, and generates output O and carry output CO according to the truth table shown in Table No. 10:

TABLE NO 10
Truth Table for 2-Bit Adder Logic Cell 4102

| I1 | I2 | C1 | O | CO |
|---|---|---|---|---|
| 0 | 0 | 0 | 0 | 0 |
| 0 | 1 | 0 | 1 | 0 |
| 1 | 0 | 0 | 1 | 0 |
| 1 | 1 | 0 | 0 | 1 |
| 0 | 0 | 1 | 1 | 0 |
| 0 | 1 | 1 | 0 | 1 |
| 1 | 0 | 1 | 0 | 1 |
| 1 | 1 | 1 | 1 | 1 |

With reference to FIG. 41C, digital CIM cell 4103 stores a weight, W, in SRAM cell 4104. It multiplies W against a received input, I2, utilizing multiply logic cell 4101, and adds the resulting product, P, to received inputs I1 and CI to generate outputs O and CO utilizing 2-bit adder logic cell 4102. In this manner, each digital CIM cell 4103 performs a one-bit-wise multiplication operation (W * I2) and adds the result to a received input (I1 and CI) to perform the vector-by-matrix multiplication operation using the stored digital value, W.

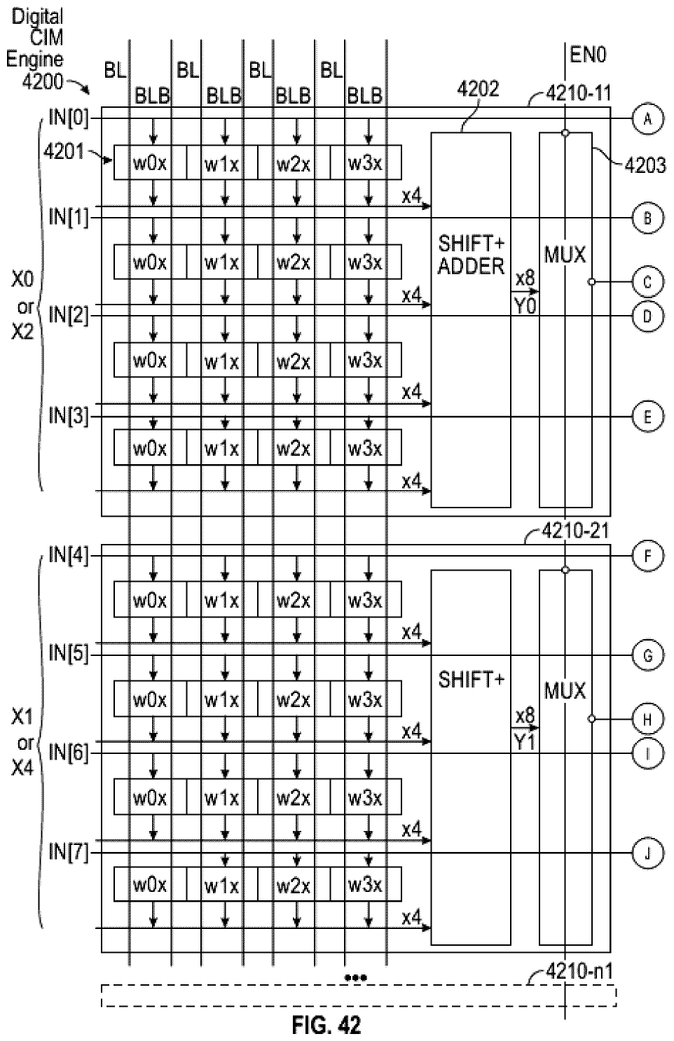

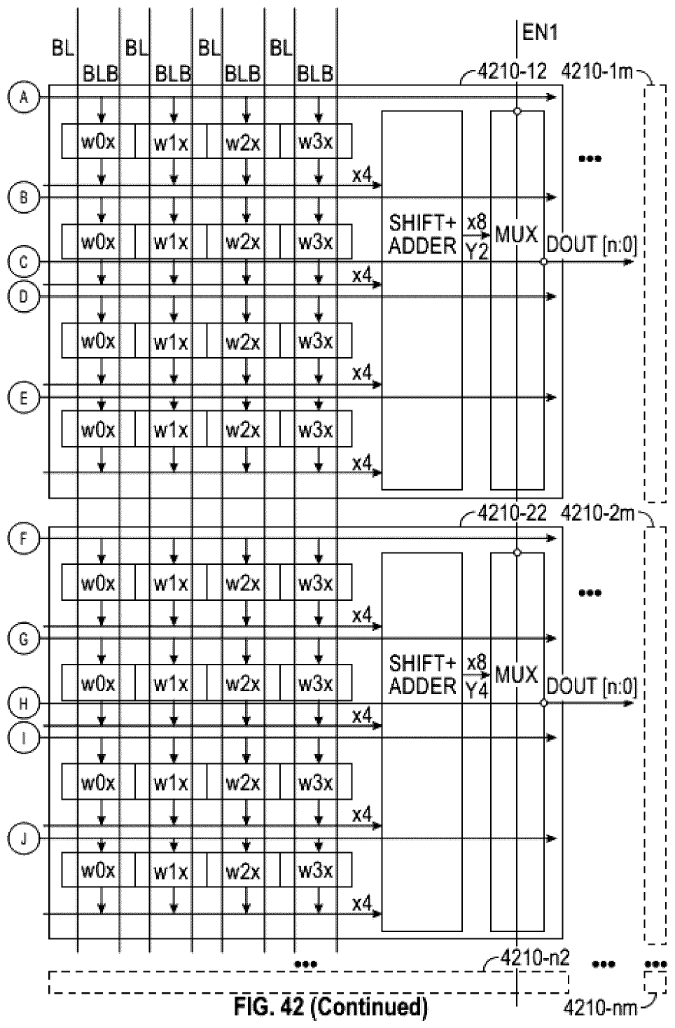

FIG. 42 depicts a portion of another example digital CIM engine 4200. Portion of digital CIM engine 4200 comprises an array of blocks, with each block comprising an array of multipliers and a shift and adder tree. In this example, blocks 4210-11, 4210-12, 4210-21, and 4210-22 are shown in detail. In the horizontal direction, digital CIM engine 4200 comprises m blocks (such as blocks 4210-11, 4210-12, . . . , 4212-1m in row 1). In the vertical direction, digital CIM engine 4200 comprises n blocks (such as blocks 4210-11, 4210-21, . . . , 4210-n1 in column 1).

Block 4210-11 will now be described as an example. The discussion as to block 4210-11 applies to the other blocks as well. Block 4210-11 comprises an array of multipliers, such as multiplier 4201, arranged in rows and columns. In this example, block 4210-11 comprises four rows and four columns of multipliers, but it is to be understood that block 4210-11 and all other blocks could instead any number of rows and columns according to the same principles discussed here, such as 8 rows and 8 columns to accommodate an 8-bit input and an 8- bit weight yielding a 16-bit output.

Digital CIM engine 4200 receives inputs for a plurality of rows. In this example, block 4210-11 receives inputs IN[0], IN[1], IN[2], and IN[3] on its four rows. Each multiplier, such as multiplier 4201, receives an input and multiplies the input by a 1-bit weight (W) stored in the multiplier, and outputs the product. The products are provided to shift and adder tree 4202, which adds the products and performs a shift operation as appropriate to reflect the fact that each row (IN[0], IN[1], IN[2], and IN[3]) represents a different digit in the binary input (IN [3:0]). That is, IN[0] represents 2⁰, IN[1] represents 2¹, IN[2] represents 2², and IN[3] represents 2³. Multiplexor block 4203 is used to enable the output from each block, such as block 4210-11, into the main output bus DOUTx in response to an enable signal, EN0. The other blocks have similar multiplexor blocks.

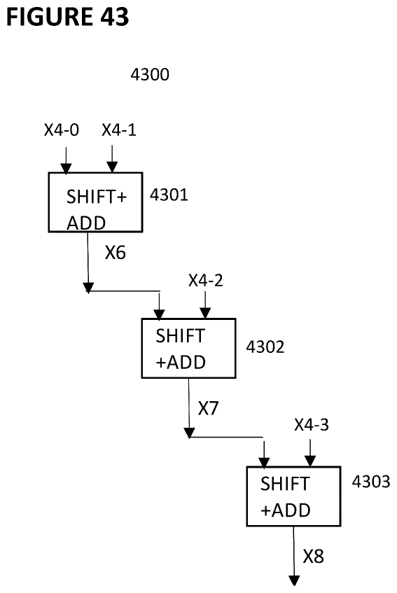

FIG. 43 depicts shift and adder tree 4300, which is an example of an implementation of shift and adder tree 4202 used in FIG. 42. Each multiplier, such as multiplier 4201, in a block such as block 4210-11, will receive a 1-bit input, multiply it by a 1-bit weight, and output a 1-bit value provided to shift and adder tree 4202. For each row, shift and adder tree 4300 receives 4 1-bit values, which it treats as a single 4-bit value arranged in the order corresponding to columns D3, D2, D1, and D0, respectively. The 4-bit value for row 0 (which received input IN[0]) is X4-0, for row 1 (which received input IN[1]) is X4-1, for row 2 (which received input IN[2]) is X4-2, and for row 3 (which received input IN[3]) is X4-3.

Shift and adder 4301 first adds X4-0 with X4-1 (where it shifts the digits of X4-1 one digit to the left due to the fact that row 1 represents the value of the input digit to the left of row 0; for example, if X4-1 is 1010, the shifted version will be 10100), yielding a 6-bit value. Shift and adder 4302 then adds that 6-bit value with a shifted version of X4-2 (where X4-2 is shifted two digits), yielding a 7-bit value. Shift and adder 4303 then adds that 7-bit value with X4-3 (where X4-3 is shifted three digits), yielding an 8-bit value, which represents the sum of the products received from the multipliers of the block.

FIGS. 44 depicts shift and adder tree 4400, which is an example of an implementation of shift and adder tree 4202 used in FIG. 42. Each multiplier, such as multiplier 4201, in a block such as block 4210-11, will receive a 1-bit input, multiply it by a 1-bit weight, and output a 1-bit value provided to shift and adder tree 4202. For each row, shift and adder tree 4400 receives 4 1-bit values, which it treats as a single 4-bit value arranged in the order corresponding to columns D3, D2, D1, and D0, respectively. The 4-bit value for row 0 (which received input IN[0]) is X4-0, for row 1 (which received input IN[1]) is X4-1, for row 2 (which received input IN[2]) is X4-2, and for row 3 (which received input IN[3]) is X4-3. Shift and adder 4401 first adds X4-0 with X4-1 (where it shifts the digits of X4-1 one digit to the left due to the fact that row 1 represents the value of the input digit to the left of row 0; for example, if X4-1 is 1010, the shifted version will be 10100), yielding a 6-bit value, X6. Shift and adder 4302 then adds a shifted version of X4-2 (where X4-2 is shifted two digits) with a shifted version of X4-3 (where X4-3 is shifted three digits), yielding a 7-bit value, X7. Shift and adder 4403 then adds that X6 and X7 together (with no shifting), yielding an 8-bit value, X8, which represents the sum of the products received from the multipliers of the block.

Another use for for digital CIM arrays is for floating point number in which a first array is sued for the exponent portion and a second array is used for the mantissa portion (fraction portion), where appropriate re-alignment and recombination of the array outputs are performed to reconstruct the final floating point number.

FIG. 45 depicts a portion of dynamic weight engine 4500. Dynamic weight engine 4500 comprises CIM dynamic weight cells 4501, 4502, 4503, and 4504, arranged into rows and columns.

CIM dynamic weight cell 4501 is representative of CIM dynamic weight cells 4502, 4503, and 4504 and other CIM memory cells in the dynamic weight engine and its operation will now be described. CIM dynamic weight cell 4501 comprises NMOS transistors 4511, 4512, 4514, and 4515, and capacitor 4513. CIM dynamic weight cell 4501 can store a weight that can be dynamically changed by modification of an input. CIM dynamic weight cell 4501 is selected when WL0 and WBL0 are asserted. When WL0 is asserted, NMOS transistors 4511 and 4514 are turned on. When WBL0 is asserted, NMOS transistor 4512 are turned on. A voltage, W, representing the weight applied by CIM dynamic weight cell 4501, is applied to WWL0 and is transferred to the gate of the NMOS transistor 4515, and stored by capacitor 4513 that is coupled between the gate of NMOS transistor 4515 and SL0, which is a source line for row 0. NMOS transistor 4515 will draw current from bit line BL0, where the drawn current is a function of the voltage, W.

CIM dynamic weight cells 4502, 4503, 4504, and other CIM dynamic weight cells in the dynamic weight engine operate in the same manner as CIM dynamic weight cell 4501.

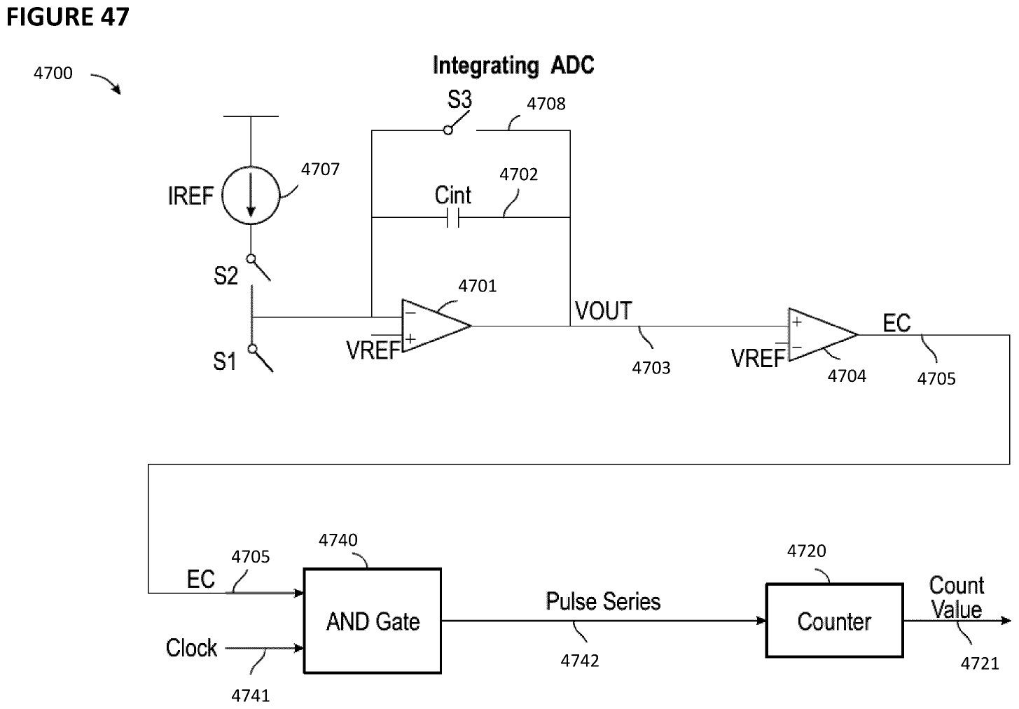

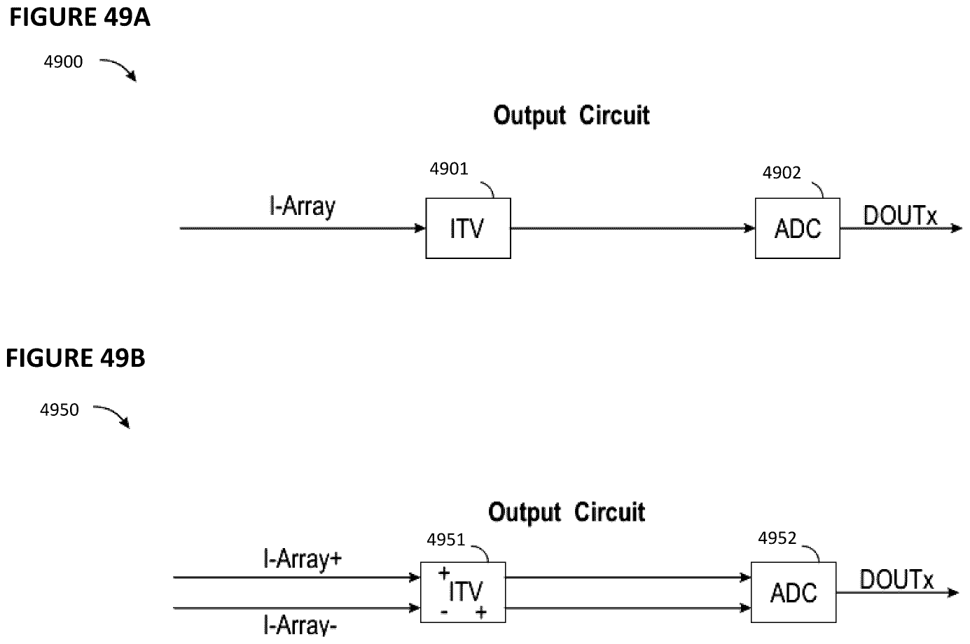

The bit lines of the CIM dynamic weight engine such as BL0 and BL1, will sum the currents drawn by all CIM dynamic weight cells connected to them, meaning that BL0 will contain the sum of all currents drawn by all CIM dynamic weight cells in column 0, BL1 will contain the sum of all currents drawn by all CIM dynamic eight cells in column 1, and so forth. This current can be converted into digital output bits by an ADC circuit such as those shown in FIGS. 47 and 49 below.

FIG. 46 depicts a portion of dynamic weight engine 4600. Dynamic weight engine 4600 comprises CIM dynamic weight cells 4601, 4602, 4603, and 4604, arranged into rows and columns.

CIM dynamic weight cell 4601 is representative of CIM dynamic weight cells 4602, 4603, and 4604 and other CIM dynamic weight cells in the dynamic weight engine and its operation will now be described. CIM dynamic weight cell 4601 comprises NMOS transistors 4611, 4612, 4613, 4615, and 4616, and capacitor 4614. CIM dynamic weight cell 4601 can store a weight that can be dynamically changed by modification of an input. CIM dynamic weight cell 4601 is selected when WL0 and WBL are asserted. When WL0 is asserted, NMOS transistors 4611 and 4615 are turned on. When WBL is asserted, NMOS transistor 4613 is turned on. A voltage, W, representing the weight applied by CIM dynamic weight cell 4601, is applied to WWL0 and is transferred to the gate of the NMOS transistor 4616, and stored by capacitor 4614 that is coupled between the gate of NMOS transistor 4616 and SL0, which is a source line for row 0. NMOS transistor 4616 will draw current from bit line BL0, where the drawn current is a function of the voltage, W.

CIM dynamic weight cells 4602, 4603, 4604, and other CIM dynamic weight cells in the dynamic weight engine operate in the same manner as CIM dynamic weight cell 4601.

The bit lines of the CIM dynamic weight engine such as BL0 and BL1, will sum the currents drawn by all CIM dynamic weight cells connected to them, meaning that BL0 will contain the sum of all currents drawn by all CIM dynamic weight cells in column 0, BL1 will contain the sum of all currents drawn by all CIM dynamic eight cells in column 1, and so forth. This current can be converted into digital output bits by an ADC circuit such as those shown in FIGS. 47 and 49 below.

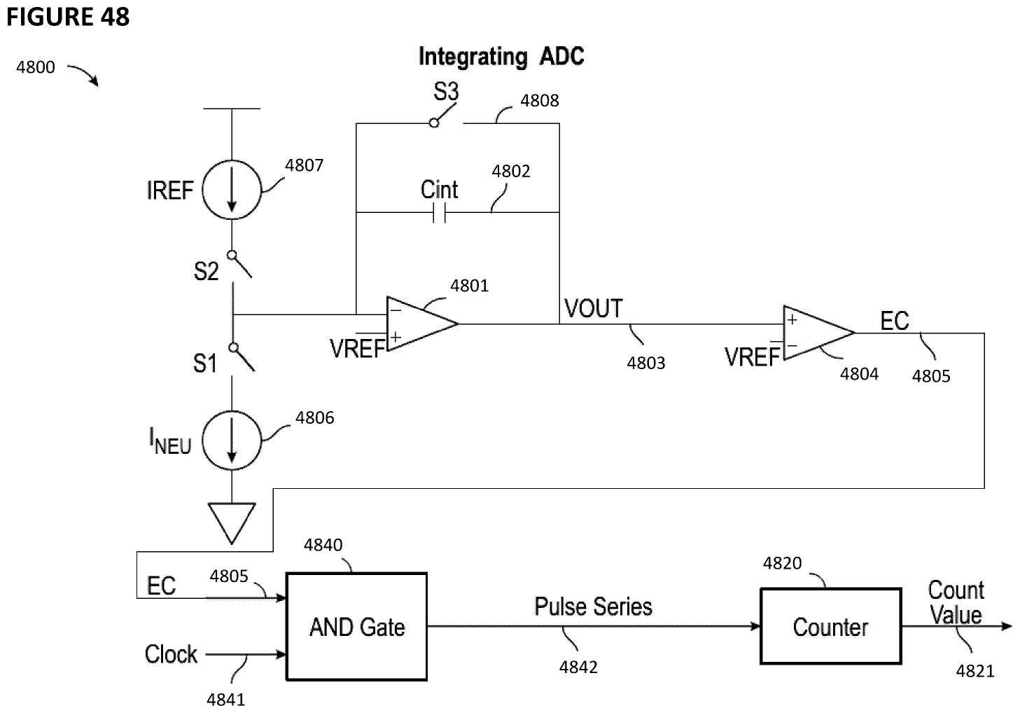

FIG. 47 depicts an example integrating ADC 4700 used to convert charge stored in the cells of the portion of digital CIM engine 3900 in FIG. 39 into digital pulses or digital output bits. Integrating ADC 4700 converts an analog output charge (charge stored in the capacitor 4702 CINT) in a neuron output block into a digital pulse whose width varies in proportion to the magnitude of the analog output current in the neuron output block. The capacitor 4702 represents all the capacitors from the selected CIM volatile SRAM memory cells being summed up (connected in parallel through pass transistor) in FIG. 39. The ADC 4700 comprises reference current 4707, op amp 4701, comparator 4704, AND gate 4740, and counter 4720. Charges of individual capacitors in the CIM volatile SRAM memory cells are summed up and then re-configured to be an integrating capacitor 4702 across the op amp 4701. The reference current 4707 discharges the total stored charge in the integrating capacitor 4702, and counter 4720 generates pulses until the discharge is complete. The pulses represent the digital output bits as shown in FIG. 48.

FIG. 48 depicts integrating ADC 4800 used to convert current received from one or more columns in analog CIM engine in FIG. 37, digital CIM engine 3800 in FIG. 38, dynamic weight engine 4500 in FIG. 45, and dynamic weight engine 4600 in FIG. 46 into digital pulses or digital output bits.

ADC 4800 converts a current, I_{NEU}, into a digital pulse, EC, whose width varies in proportion to the magnitude of the current. An integrator comprising integrating op-amp 4801 and integrating capacitor 4802 integrates I_{NEU} 4806 versus a reference current, IREF, provided by current source 4807.

Optionally, current source 4807 can comprise a bandgap filter with a temperature coefficient of 0 or with a temperature coefficient that tracks the neuron current, I_{NEU}. A temperature coefficient that tracks I_{NEU} can be obtained from a lookup table (not shown) containing values determined during a testing phase.

During an initialization phase, switch 4808 is closed. Vout 4803 and the input to the negative terminal of operational amplifier 4801 then will become equal to VREF. Thereafter, switch 4808 is opened, and switch S2 is closed, while switch S1 remains open, and during a fixed time period tref, the constant reference current IREF 4807 is up-integrated. During the fixed time period tref, Vout rises, and its slope is reflective of the value of constant reference current IREF 4807. Thereafter, switch S2 is opened, and switch S1 is closed, and during a period tmeas, neuron current I_{NEU} 4806 is down integrated for a time period tmeas (during which period Vout falls), where tmeas is the time to down integrate Vout to VREF, as indicated by the output of comparator 4804 changing.

Output EC 4805 will be high when VOUT>VREFV and will be low otherwise. EC 4805 therefore generates a pulse whose width reflects the period tmeas, which in turn is proportional to the current I_{NEU} 4806. Thus, the output neuron current I_{NEU} 4806 is converted into a digital pulse EC 4805, where the width of digital pulse EC 4805 varies in proportion to the magnitude of output neuron current I_{NEU} 4806.

The current I_{NEU} 4806 is =tmeas/tref * IREF. For example, for a desired output bit resolution of 10 bits, tref is a time period equal to 1024 clock cycles. The period tmeas varies from a period equal to 0 to 1024 clock cycles depending on the value of I_{NEU} 4806 and the value of Iref. The neuron current I_{NEU} 4806 affects the rate and slope of charging.

Optionally, the output pulse EC 4805 can be converted into a series of pulses of uniform period for transmission to the next block of circuitry, such as the input block of CIM engine. At the beginning of period tmeas, output EC 4805 is input into AND gate 4840 with reference clock 4841. The output will be pulse series 4842 (where the frequency of the pulses in pulse series 4842 is the same as the frequency of clock 4841) during the period when VOUT>VREF. The number of pulses is proportional to the period tmeas, which is proportional to the current I_{NEU} 4806.

Optionally, pulse series 4843 can be input to counter 4820, which will count the number of pulses in pulse series 4842 and will generate count value 4821, which is a digital count of the number of pulses in pulse series 4842, which is directly proportional to neuron current I_{NEU} 4806. Count value 4821 comprises a set of digital bits. In another example, integrating ADC 4800 can convert neuron current I_{NEU} 4806 into a pulse where the width of the pulse is inversely proportionally to the magnitude of neuron current I_{NEU} 4806. This inversion can be done in a digital or analog manner, and converted into a series of pulses or digital bits for output to follow on circuitry.

FIG. 49A depicts an example output circuit 4900 that can convert the array current into digital output bits. The output circuit 4900 comprises current-to-voltage converter (ITV) 4901 and analog-to-digital converter (ADC) 4902. The ITV 4901 converts the array current into a voltage which is then digitized by the ADC 4902. The ADC 4902 can be a successive approximation (SAR) ADC.

FIG. 49B depicts example output circuit 4950 comprising ITV 4951 that receives a differential input and generates a differential output and ADC 4952 that receives a differential input from the differential output of ITV 4951 and generates a single-ended digital output. Examples of implementations of current-to-voltage converters and analog-to-digital converters are described in U.S. patent application Ser. No. 17/521,772, which is incorporated by reference herein.

Other examples for analog and digital CIM engines can utilize NAND memory, resistive RAM (ReRAM), magnetic RAM (MRAM), or dynamic RAM (DRAM), without limitation.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

1. A system comprising:
an analog computation-in-memory engine to perform operations in a first layer in a neural network; and
a digital computation-in-memory engine to perform operations in a second layer different than the first layer in the neural network.

2. The system of claim 1, comprising:
a system bus coupled to the analog computation-in-memory engine and the digital computation-in-memory engine.

3. The system of claim 1, wherein the analog computation-in-memory engine comprises a plurality of non-volatile memory cells arranged into rows and columns.

4. The system of claim 3, wherein the non-volatile memory cells are stacked-gate flash memory cells.

5. The system of claim 3, wherein the non-volatile memory cells are split-gate flash memory cells.

6. The system of claim 1, wherein the digital computation-in-memory engine comprises a plurality of static random access memory (SRAM) cells arranged into rows and columns.

7. The system of claim 1, wherein the digital computation-in-memory engine comprises a plurality of CIM digital cells arranged into rows and columns.

8. The system of claim 7, wherein the plurality of CIM digital cells respectively comprise a multiply logic cell and a 2-bit adder logic cell.

9. The system of claim 7, wherein the digital computation-in-memory engine comprises a shift and adder tree coupled to the plurality of CIM digital cells.

10. A system comprising:
an analog computation-in-memory engine to perform operations in a first layer in a neural network;
a digital computation-in-memory engine to perform operations in a second layer in the neural network; and
a dynamic weight engine to perform operations in a third layer in the neural network;
wherein the first layer, the second layer, and the third layer are different layers in the neural network.

11. The system of claim 10, comprising:
a system bus coupled to the analog computation-in-memory engine, the digital computation-in-memory engine, and the dynamic weight engine.

12. The system of claim 10, wherein the analog computation-in-memory engine comprises a plurality of non-volatile memory cells arranged into rows and columns.

13. The system of claim 12, wherein the non-volatile memory cells are stacked-gate flash memory cells.

14. The system of claim 12, wherein the non-volatile memory cells are split-gate flash memory cells.

15. The system of claim 10, wherein the digital computation-in-memory engine comprises a plurality of static random access memory (SRAM) cells arranged into rows and columns.

16. The system of claim 10, wherein the digital computation-in-memory engine comprises a plurality of CIM digital cells.

17. The system of claim 16, wherein the plurality of CIM digital cells respectively comprise a multiply logic cell and a 2-bit adder logic cell.

18. The system of claim 16, wherein the digital computation-in-memory engine comprises a shift and adder tree coupled to the plurality of CIM digital cells.

19. A method comprising:
performing vector-by-matrix multiplication operations in a first layer of a neural network using a digital computation-in-memory engine; and
performing vector-by-matrix multiplication operations in a second layer different than the first layer of the neural network using an analog computation-in-memory engine.

20. The method of claim 19, wherein the analog computation-in-memory engine comprises a plurality of non-volatile memory cells arranged into rows and columns.

21. A method comprising:
performing vector-by-matrix multiplication operations in a first layer of a neural network using a digital computation-in-memory engine;
performing vector-by-matrix multiplication operations in a second layer of the neural network using an analog computation-in-memory engine; and
performing vector-by-matrix multiplication operations in a third layer of the neural network using a dynamic weight engine;
wherein the first layer, the second layer, and the third layer are different layers in the neural network.

22. The method of claim 21, wherein the analog computation-in-memory engine comprises a plurality of non-volatile memory cells arranged into rows and columns.

23. A method comprising:
performing vector-by-matrix multiplication operations in a first layer of a neural network using one of an analog computation-in-memory engine, a digital computation-in-memory engine, and a dynamic weight engine; and
performing vector-by-matrix multiplication operations in a second layer of a neural network using another of the analog computation-in-memory engine, the digital computation-in-memory engine, and the dynamic weight engine.

24. A method comprising:
storing weights received from an analog computation-in-memory engine in one or more of a digital computation-in-memory engine, a digital computation engine, and a dynamic weight engine.
